(19) United States
(12) Patent Application Publication
(10) Pub. No.: US 2025/0336747 A1
(43) Pub. Date: Oct. 30, 2025

(54) SEMICONDUCTOR PACKAGE WITH DIE ISOLATION

(71) Applicant: Texas Instruments Incorporated, Dallas, TX (US)

(72) Inventors: Kashyap Mohan, Irving, TX (US); Daiki Komatsu, Beppu-shi (JP)

(21) Appl. No.: 18/650,470

(22) Filed: Apr. 30, 2024

(51) Int. Cl. H01L 23/31; G01R 33/00; H01L 21/56; H01L 21/78; H01L 21/784; H01L 23/00; H01L 23/495

(52) U.S. Cl. CPC H01L 23/3185; H01L 21/561; H01L 21/78; H10D 89/013; G01R 33/0047; H01L 23/4951; H01L 23/49513; H01L 24/29; H01L 24/32; H01L 24/48; H01L 24/49; H01L 24/73; H01L 2224/2919; H01L 2224/32245; H01L 2224/48091; H01L 2224/48245; H01L 2224/49176; H01L 2224/73265; H01L 2924/0665

(57) ABSTRACT

A semiconductor package includes a microelectronic die with an electrically conductive substrate that has an isolation dielectric layer on a back surface of the substrate. The isolation dielectric layer extends onto perimeter sidewalls of the substrate. The isolation dielectric layer on the back surface is attached to an electrically conductive member of a lead frame. The isolation dielectric layer isolates the substrate from the electrically conductive member. The microelectronic die is formed by forming isolation kerfs in the substrate, extending from the back surface. Sides of the isolation kerfs form perimeter sidewalls of the substrate. The isolation dielectric layer is formed on the back surface and in the isolation kerfs. The microelectronic die is singulated through the isolation kerfs. The isolation dielectric layer remains on the back surface and the perimeter sidewalls.

### TECHNICAL FIELD

This disclosure relates to the field of semiconductor packages. More particularly, but not exclusively, this disclosure relates to semiconductor packages with lead frames.

### BACKGROUND

Semiconductor packages provide electrical connections to external circuitry. Traditional semiconductor packaging methods often involve attaching chips to lead frames, which act as a structural support and facilitate electrical connections. Lead frames are typically made of a conductive material, such as copper or alloy, and are designed with intricate patterns to accommodate the placement and bonding of semiconductor chips. The chips are attached to the lead frames and are electrically connected to leads of the lead frame. There is an ongoing demand for assembly cost reduction and miniaturization of electronic devices.

### SUMMARY

A semiconductor package includes a microelectronic die having an electrically conductive substrate. The semiconductor package includes an isolation dielectric layer on a back surface of the substrate, which extends onto perimeter sidewalls of the substrate that are contiguous with the back surface. The semiconductor package includes a lead frame, which has electrically conductive members. The isolation dielectric layer on the back surface is attached to an electrically conductive member.

The microelectronic device is formed by forming isolation kerfs in the substrate. The isolation kerfs extend partway into the substrate from the back surface, forming the perimeter sidewalls. The isolation dielectric layer is formed on the back surface, extending into the isolation kerfs. The microelectronic die is singulated through the isolation kerfs, leaving the isolation dielectric layer on the back surface and the perimeter sidewalls. The isolation dielectric layer on the back surface is attached to the electrically conductive member of the lead frame.

### BRIEF DESCRIPTION OF THE VIEWS OF THE DRAWINGS

FIG. 1A through FIG. 1N are cross-sections and top views of an example semiconductor package, depicted in stages of an example method of formation.

FIG. 2A through FIG. 2L are cross-sections and top views of another example semiconductor package, depicted in stages of another example method of formation.

FIG. 3A through FIG. 3L are cross-sections, top views, and a bottom view of a further example semiconductor package, depicted in stages of a further example method of formation.

FIG. 4A through FIG. 4H are cross-sections and top views of a further example semiconductor package, depicted in stages of a further example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

A semiconductor package includes a microelectronic die, such as an integrated circuit, a discrete semiconductor device, a microelectrical mechanical system (MEMS) device, an electro-optical device, a microfluidic device, or a micro-optical mechanical system device. The microelectronic die has an electrically conductive substrate, such as a silicon substrate. The substrate has a back surface, opposite from a connection surface, and perimeter sidewalls contiguous with the back surface. The semiconductor package includes an isolation dielectric layer on the back surface, extending onto perimeter sidewalls of the substrate that are contiguous with the back surface. The perimeter sidewalls may extend completely around the microelectronic die, or may extend along two opposite sides of the microelectronic die. The perimeter sidewalls may be recessed from edges of the connection surface. The semiconductor package includes a lead frame, which has electrically conductive members. The isolation dielectric layer on the back surface is attached to an electrically conductive member. The semiconductor package includes electrical connections from the connection surface to the leads.

The microelectronic device is formed by forming isolation kerfs in the substrate. The isolation kerfs extend partway into the substrate from the back surface, forming the perimeter sidewalls. The isolation dielectric layer is formed on the back surface, extending into the isolation kerfs. The microelectronic die is singulated through the isolation kerfs, leaving the isolation dielectric layer on the back surface and the perimeter sidewalls. The isolation dielectric layer on the back surface is attached to the electrically conductive member of the lead frame. Subsequently, the electrical connections are formed between the connection surface and the leads.

It is noted that terms such as top, bottom, back, over, and under may be used in this disclosure. These terms should not be construed as limiting the position or orientation of a structure or element, but should be used to provide spatial relationship between structures or elements. For the purposes of this disclosure, the terms “lateral” and “laterally” refer to a direction parallel to a plane of an instant back surface of a substrate of the microelectronic die, and the term “vertically” is understood to refer to a direction perpendicular to the plane of the back surface.

For the purposes of this disclosure, when a material is disclosed to include “primarily” a type of composition, the material is more than 90 percent by weight of the disclosed type of ingredient. For example, a dielectric material disclosed as including primarily inorganic material has more than 90 percent by weight inorganic material, such as silicon dioxide or silicon nitride. For another example, a dielectric material disclosed as including primarily organic material has more than 90 percent by weight organic material, such as epoxy, parylene, or silicone.

It is to be noted that in the text as well as in all of the Figures, the respective structures will be termed the “semiconductor package” and will be referred to by the number “100” though the device is not yet a semiconductor package 100 until some of the last stages of the methods of formation described herein. This is done primarily for the convenience of the reader.

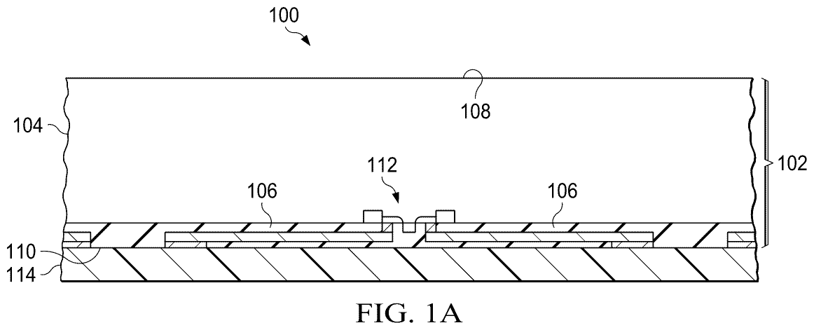

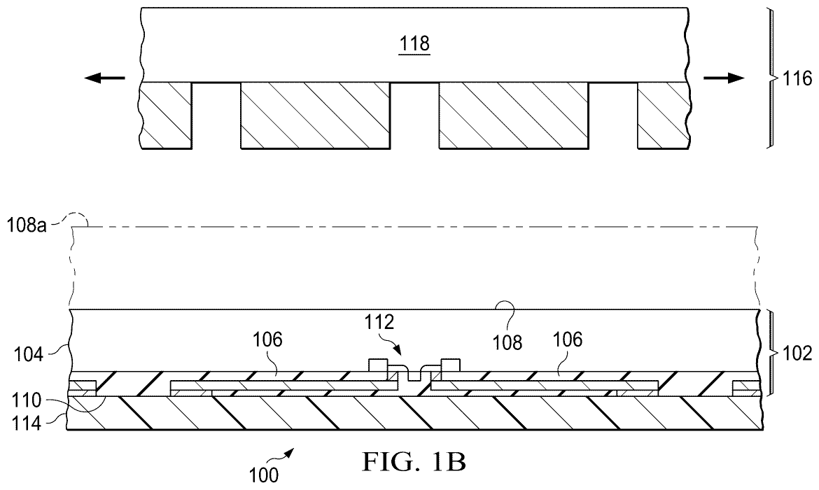

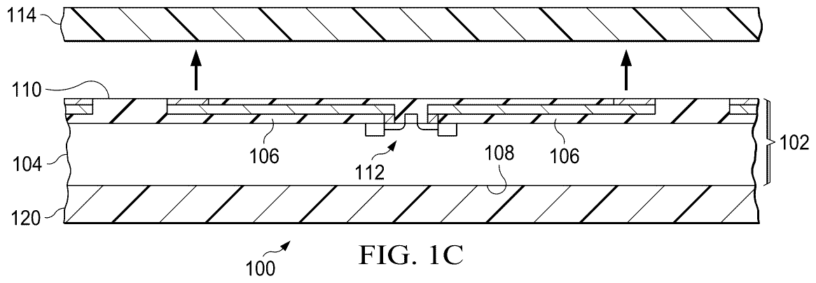

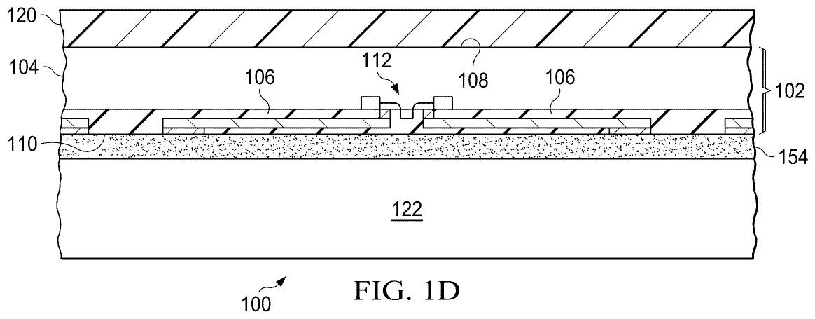

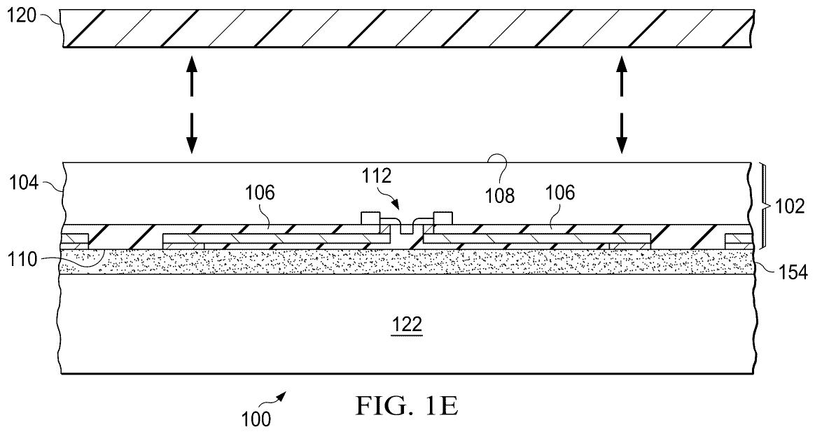

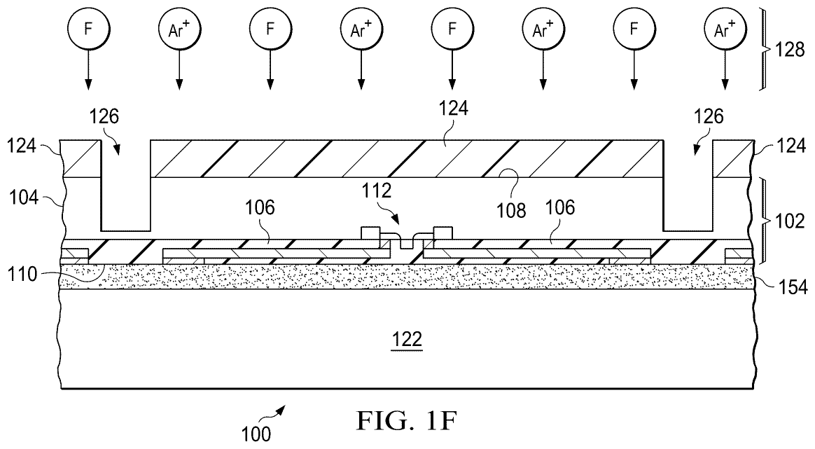

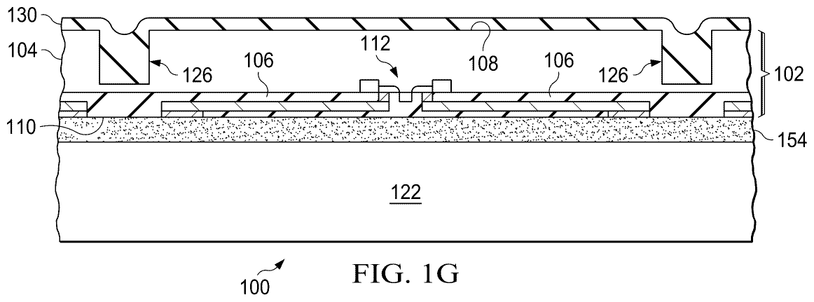

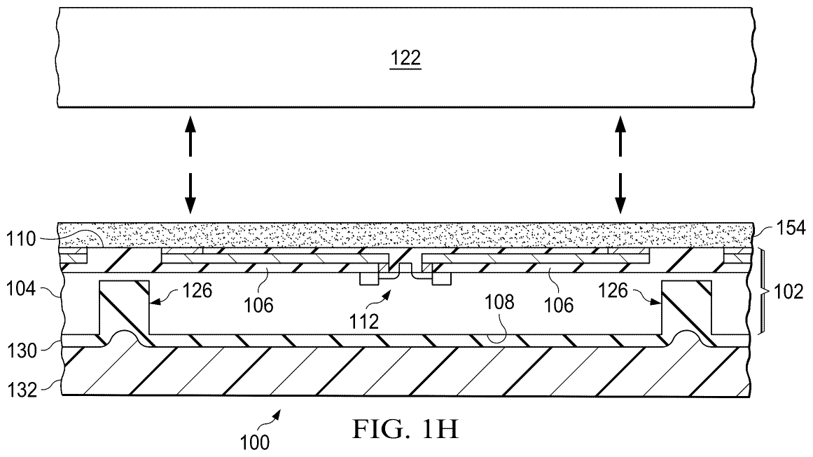

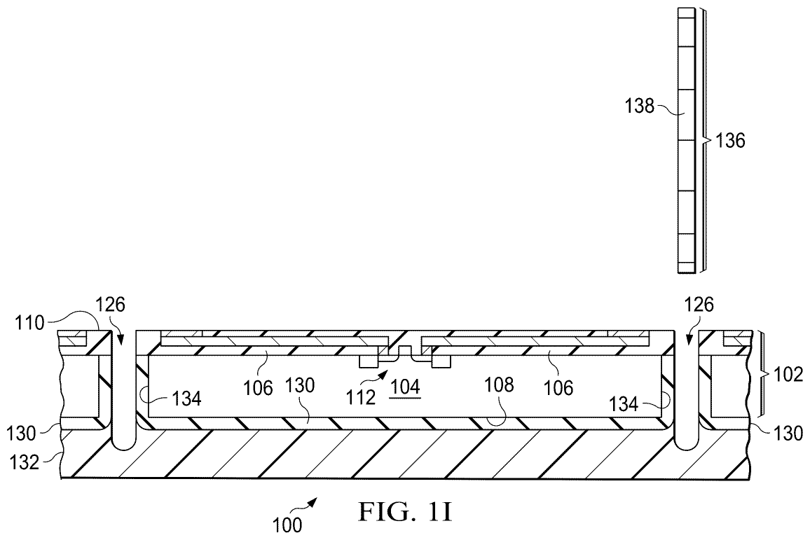

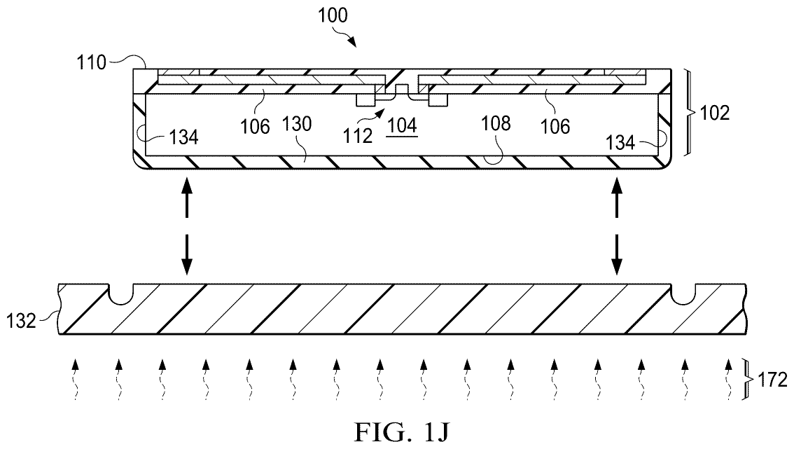

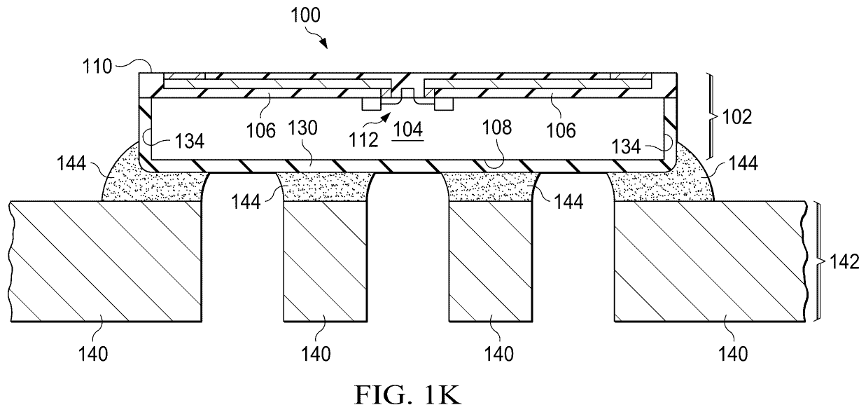

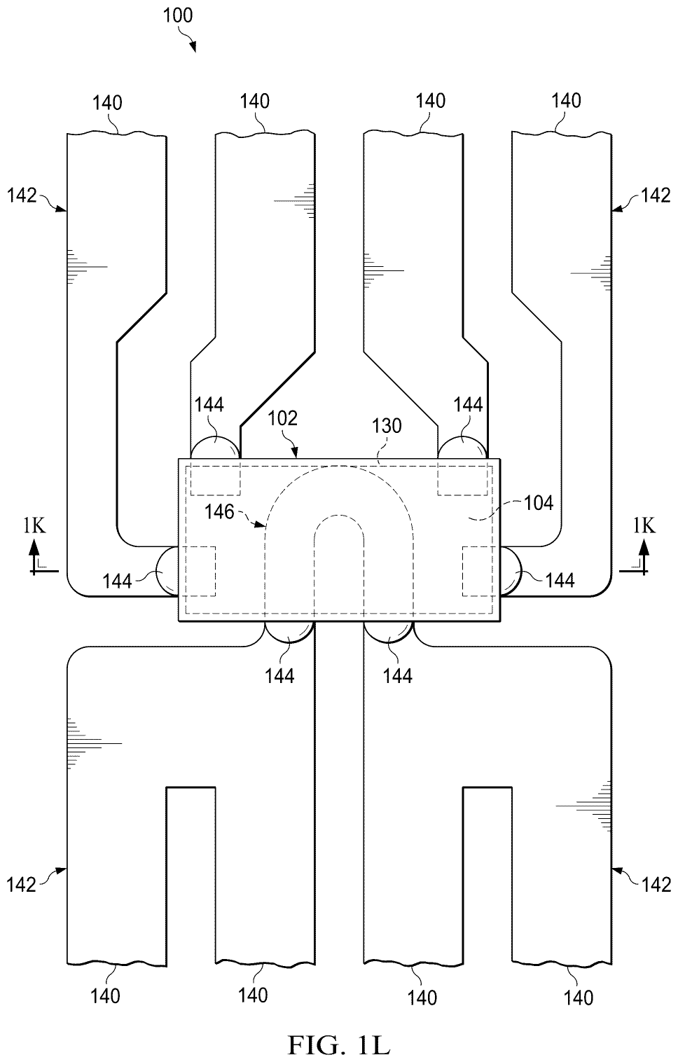

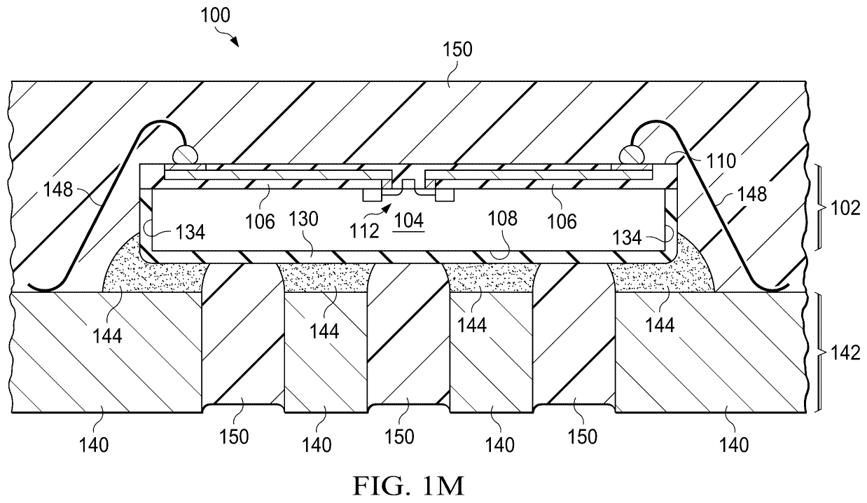

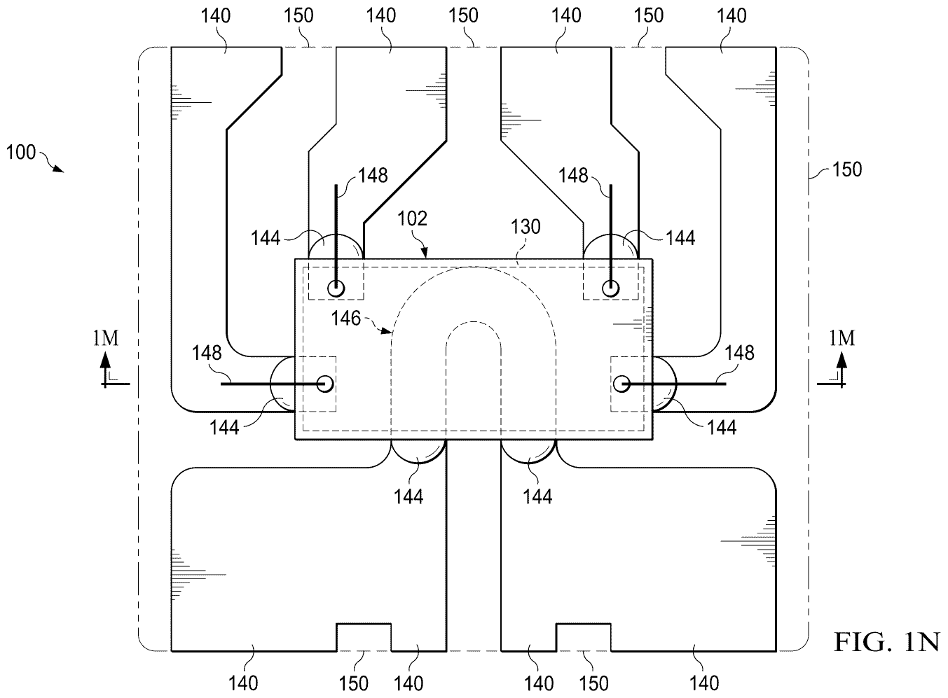

FIG. 1A through FIG. 1N are cross-sections and top views of an example semiconductor package, depicted in stages of an example method of formation. Referring to FIG. 1A, which is a cross section, the semiconductor package 100 includes a microelectronic die 102. The microelectronic die 102 may be manifested as an integrated circuit, a discrete semiconductor device, a MEMS device, an electro-optical device, a microfluidic device, or a micro-optical mechanical system device, by way of example. Other manifestations of the microelectronic die 102 are within the scope of this example. The microelectronic die 102 includes a substrate 104 that is electrically conductive. The substrate 104 may include silicon, gallium arsenide, gallium nitride, silicon carbide, or other semiconductor material. The microelectronic die 102 includes an interconnect region 106 on the substrate 104. The substrate 104 has a back surface 108 located opposite from the interconnect region 106. The microelectronic die 102 has a connection surface 110 on the interconnect region 106, located opposite from the substrate 104. The microelectronic die 102 includes an electronic component 112 in the substrate 104, adjacent to, and possibly extending into, the interconnect region 106. In this example, the electronic component 112 is depicted as a metal oxide semiconductor (MOS) transistor. Other manifestations for the electronic component 112, such as an amplifier, a sensor, a signal driver, or a transducer, are within the scope of this example. The connection surface 110 includes bond pads or other input/output structures that are electrically connected to the electronic component 112 through conductive members in the interconnect region 106. The microelectronic die 102 may be part of a wafer having additional microelectronic dies, not specifically shown. FIG. 1A depicts the microelectronic die 102 in an inverted orientation from the typical orientation of the microelectronic die 102 during fabrication of the electronic component 112; the microelectronic die 102 is typically oriented with the substrate 104 “down” and the interconnect region 106 “up,” over the substrate 104.

The microelectronic die 102 is attached to a back grind tape 114 at the connection surface 110, thus exposing the back surface 108 of the substrate 104. The inverted orientation depicted in FIG. 1A may facilitate attaching the connection surface 110 to the back grind tape 114. The back grind tape 114 may be a thermal release tape, which releases the microelectronic die 102 upon heating, may be an ultraviolet (UV) release tape, which releases the microelectronic die 102 upon exposure to UV radiation, or may be a peel release tape, which releases the microelectronic die 102 by having the back grind tape 114 peeled away from the connection surface 110.

Referring to FIG. 1B, which is a cross section, a portion of the substrate 104 is removed at the back surface 108 by a back grind process 116 using a back grinding wheel 118. FIG. 1B depicts the microelectronic die 102 after the back grind process 116 is completed. The initial back surface 108a is shown in dashed lines. In this example, more than half of the substrate 104 may be removed by the back grind process 116. Other processes for removing the portion of the substrate 104, such as a chemical mechanical polishing (CMP) process, are within the scope of this example.

Referring to FIG. 1C, which is a cross section, the back surface 108 of the substrate 104 is attached to a temporary transfer base 120. FIG. 1C depicts the microelectronic die 102 in an inverted orientation compared to FIG. 1B, which may facilitate attaching the back surface 108 to the temporary transfer base 120. The temporary transfer base 120 may be implemented as a releasable tape, such as a thermal release tape, a UV release tape, or a peel release tape.

The back grind tape 114 is removed from the connection surface 110. For versions of this example in which the back grind tape 114 is a thermal release tape, the back grind tape 114 may be heated to facilitate removal from the connection surface 110. For versions of this example in which the back grind tape 114 is a UV release tape, the back grind tape 114 may be exposed to UV radiation to facilitate removal. For versions of this example in which the back grind tape 114 is a peel release tape, the back grind tape 114 may be peeled from one edge of the wafer containing the microelectronic die 102 to facilitate removal. After the back grind tape 114 is removed, any residue, such as remaining adhesive, not specifically shown, on the connection surface 110 may be removed. The residue may be removed by a solvent spray or an atmospheric plasma process, by way of example.

Referring to FIG. 1D, which is a cross section, the microelectronic die 102 is again inverted and attached to a processing support structure 122 at the connection surface 110, through a releasable adhesive 154. The processing support structure 122 may be implemented as a rigid substrate, such as a silicon wafer, a ceramic wafer, a sapphire wafer, or a silicone lamina with reinforcing fibers to provide improved structural stability. The releasable adhesive 154 may be implemented as a UV release adhesive, which releases the connection surface 110 upon exposure to UV radiation, or may be implemented as a thermal release adhesive, which releases the connection surface 110 upon heating, by way of example.

Referring to FIG. 1E, which is a cross section, the temporary transfer base 120 is removed from the back surface 108. The temporary transfer base 120 may be exposed to heat, UV radiation, or a mechanical peel process, as appropriate, to facilitate removal. Any residue, not specifically shown, on the back surface 108 from the temporary transfer base 120 may be removed.

Referring to FIG. 1F, which is a cross section, a kerf etch mask 124 is formed on the back surface 108, exposing the back surface 108 in areas for isolation kerfs 126. The kerf etch mask 124 may include photoresist, formed by a photolithographic process. The kerf etch mask 124 may include organic anti-reflection material, such as a bottom anti-reflection coating (BARC) layer. The kerf etch mask 124 may include inorganic hard mask material, such as silicon nitride, silicon dioxide, silicon oxynitride, or silicon carbonitride, by way of example.

Substrate material is removed from the substrate 104 where exposed by the kerf etch mask 124 to form the isolation kerfs 126. In this example, the substrate material may be removed by a deep reactive ion etch (RIE) process 128 using fluorine radicals and argon ions, as indicated in FIG. 1F. In one version of this example, the deep RIE process 128 may be implemented as an iterative two-step process, sometimes referred to as a Bosch process, alternating between etching the substrate 104 at the bottom of the isolation kerfs 126 and forming a passivating polymer on sidewalls of the isolation kerfs 126. In another version of this example, the deep RIE process 128 may be implemented as continuous process, concurrently etching the substrate 104 and forming a passivating polymer on the sidewalls. The deep RIE process 128 may be implemented in an inductively coupled plasma (ICP) tool, to provide independent control over radical densities and ion energies. In this example, the isolation kerfs 126 may extend more than halfway through the substrate 104, as depicted in FIG. 1F.

After the isolation kerfs 126 are formed, the kerf etch mask 124 is removed. Organic material in the kerf etch mask 124 may be removed by exposure to an oxygen plasma, exposure to ozone, an oxidizing wet clean process, or a combination thereof. Inorganic material in the kerf etch mask 124 may be removed by exposure to a plasma etch process using halogen radicals, such as fluorine radicals.

Referring to FIG. 1G, which is a cross section, an isolation dielectric layer 130 is formed on the back surface 108 and in the isolation kerfs 126. In this example, the isolation dielectric layer 130 may be formed by applying a liquid dielectric precursor material, not specifically shown, to the back surface 108 and the isolation kerfs 126 by a spin coating process or a spray process. Forming the isolation dielectric layer 130 using a spin coating process or a spray process may advantageously reduce process cost and complexity compared to using vacuum processes. The rigidity of the processing support structure 122 may advantageously support the microelectronic die 102 during the spin coating process or the spray process.

The liquid dielectric precursor material may include organic material such as epoxy, polyphenylene ether (PPE), silicone, hydrogen silsesquioxane (HSQ), or perhydropolysilazane, for example. The liquid dielectric precursor material may be cured by a heating process, or by exposure to UV radiation, for example. The isolation dielectric layer 130 may include filler particles, such as silicon dioxide particles or aluminum oxide particles, to increase a dielectric breakdown strength. Other compositions for the isolation dielectric layer 130 are within the scope of this example. The isolation dielectric layer 130 may fill the isolation kerfs 126, as depicted in FIG. 1G.

Referring to FIG. 1H, which is a cross section, the microelectronic die 102 is again inverted and the isolation dielectric layer 130 is attached to a dicing tape 132. The dicing tape 132 may be implemented as a thermal release tape, a UV release tape, or a peel release tape, by way of example.

The processing support structure 122 is removed from the connection surface 110. The releasable adhesive 154 may be exposed to heat or UV radiation, as appropriate, to facilitate removal. Any residue on the connection surface 110 from the releasable adhesive 154 may be removed, for example by a solvent spray.

Referring to FIG. 1I, which is a cross section, the microelectronic die 102 is singulated through the isolation kerfs 126, leaving the isolation dielectric layer 130 on perimeter sidewalls 134 of the substrate 104. In this example, the isolation dielectric layer 130 on the perimeter sidewalls 134 extends around all sides of the microelectronic die 102. The microelectronic die 102 may be singulated by a saw process 136 using a diamond saw blade 138, as indicated in FIG. 1I. Other methods of singulating the microelectronic die 102, such as plasma dicing or laser dicing, are within the scope of this example. The connection surface 110 may be coated with a protective film, such as a polymer material, not specifically shown, while the microelectronic die 102 is singulated. The polymer material is subsequently removed.

FIG. 1J, which is a cross section, the dicing tape 132 is separated from the isolation dielectric layer 130. The dicing tape 132 may be expanded to laterally separate the microelectronic die 102 from adjacent die. In versions of this example in which the dicing tape 132 is implemented as a heat release tape, the dicing tape 132 may be separated by heating the dicing tape 132 in a heating process 172, as depicted schematically in FIG. 1J, such as a hot plate process. In versions of this example in which the dicing tape 132 is implemented as a UV release tape, the dicing tape 132 may be separated by exposing the dicing tape 132 to UV radiation. In versions of this example in which the dicing tape 132 is implemented as a peel release tape, the dicing tape 132 may be separated by a peeling process. The microelectronic die 102 and the isolation dielectric layer 130 may be lifted from the dicing tape 132 by pick-and-place equipment, not specifically shown.

Referring to FIG. 1K and FIG. 1L, which are a cross section and a top view, respectively, the isolation dielectric layer 130 is attached to leads 140 of a lead frame 142. The leads 140 are electrically conductive members of the lead frame 142. The leads 140 may include copper, alloy 42, or other suitable electrically conductive material. The isolation dielectric layer 130 is attached to the leads 140 though a die attach material 144. In this example, the die attach material 144 may be implemented as a die attach paste 144. The die attach paste 144 may include epoxy, by way of example. In this example, the microelectronic die 102 may include a magnetic sensor, not specifically shown, such as a Hall magnetic sensor, and a portion of the leads 140 may be configured in a Hall current path 146 to provide a signal magnetic field under the magnetic sensor in the microelectronic die 102. The isolation dielectric layer 130 extends vertically past the die attach material 144 along the perimeter sidewalls 134, so that the substrate 104 is isolated from the die attach material 144 by the isolation dielectric layer 130. The die attach material 144 does not directly contact the substrate 104.

Referring to FIG. 1M and FIG. 1N, which are a cross section and a top view, respectively, electrical connections 148 are formed between the microelectronic die 102 at the connection surface 110 and the leads 140. The electrical connections 148 may be implemented as wire bonds 148, as depicted in FIG. 1M and FIG. 1N, or may be implemented as ribbon bonds, clips, or printed connections by an additive manufacturing process such as extrusion printing. The leads 140 are electrically connected to the electronic component 112 through the electrical connections 148 and interconnect lines and vias in the interconnect region 106, as indicated in FIG. 1M.

A packaging material 150, such as a mold compound, is formed on the microelectronic die 102 and the leads 140. The leads 140 are severed from the lead frame 142 of FIG. 1K and FIG. 1L. The leads 140 are exposed at an exterior of the semiconductor package 100.

The isolation dielectric layer 130 electrically isolates the substrate 104 from the leads 140 which extend under the substrate 104, advantageously enabling the semiconductor package 100 to be reliably operated with different potentials on the leads 140. In particular, in this example, the leads 140 configured in the Hall current path 146 may be operated at a higher potential than the substrate 104.

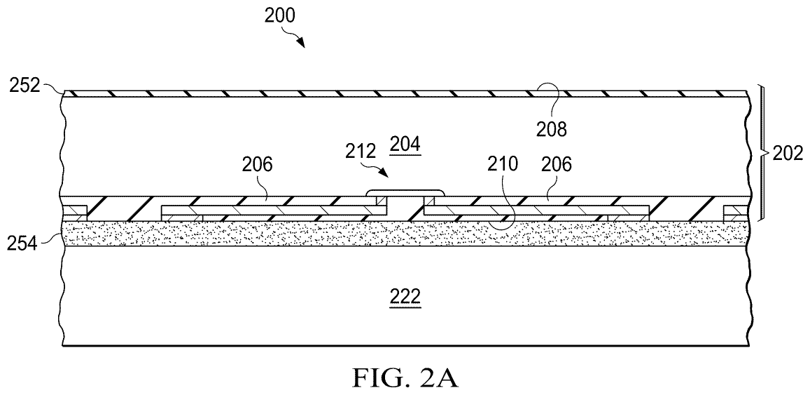

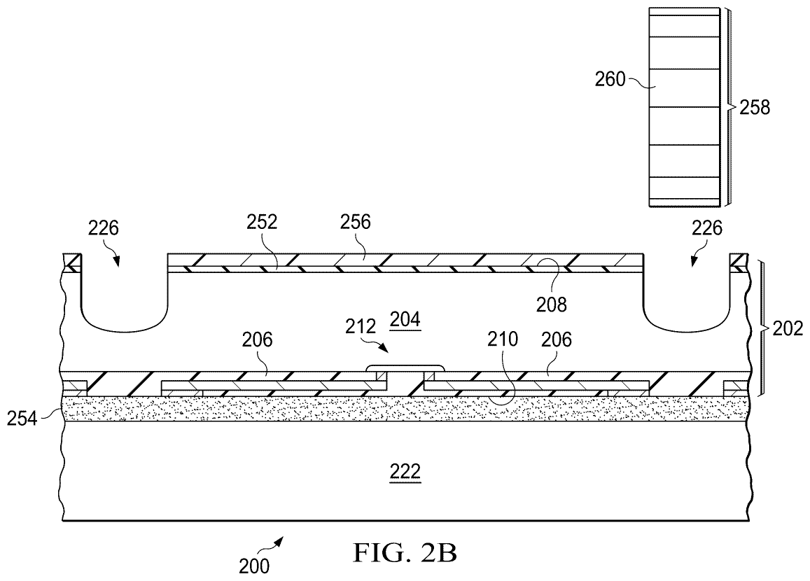

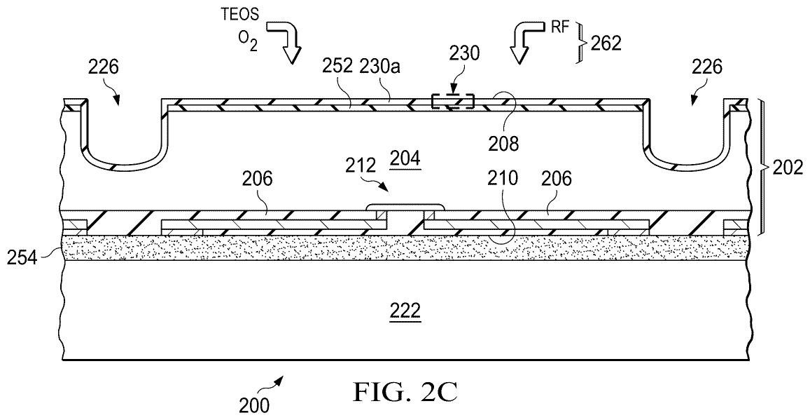

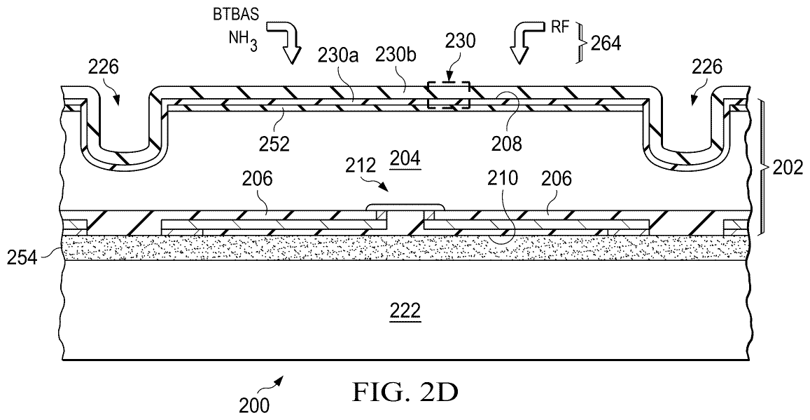

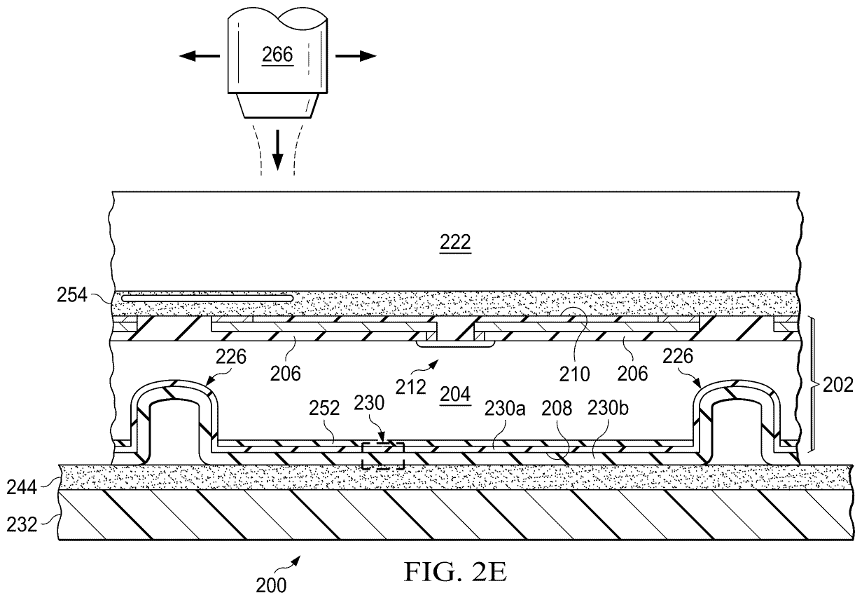

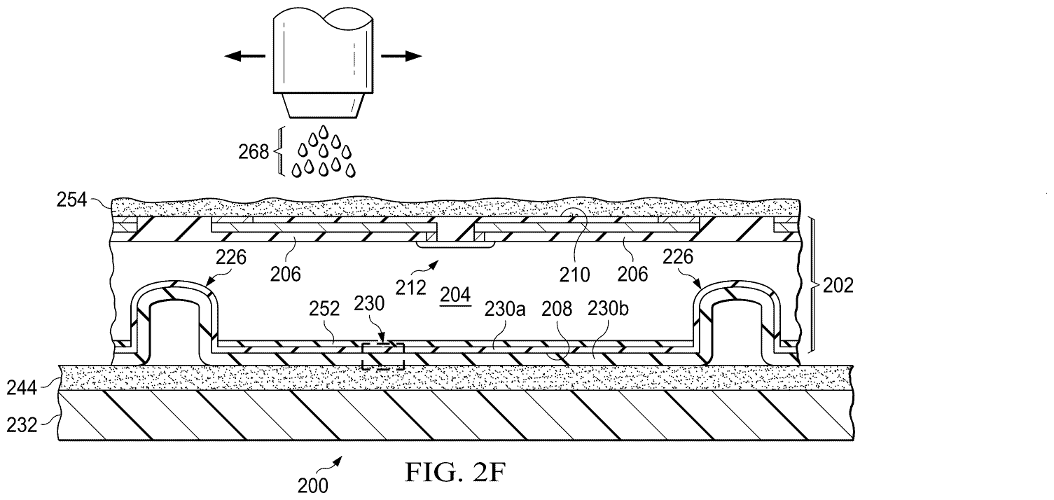

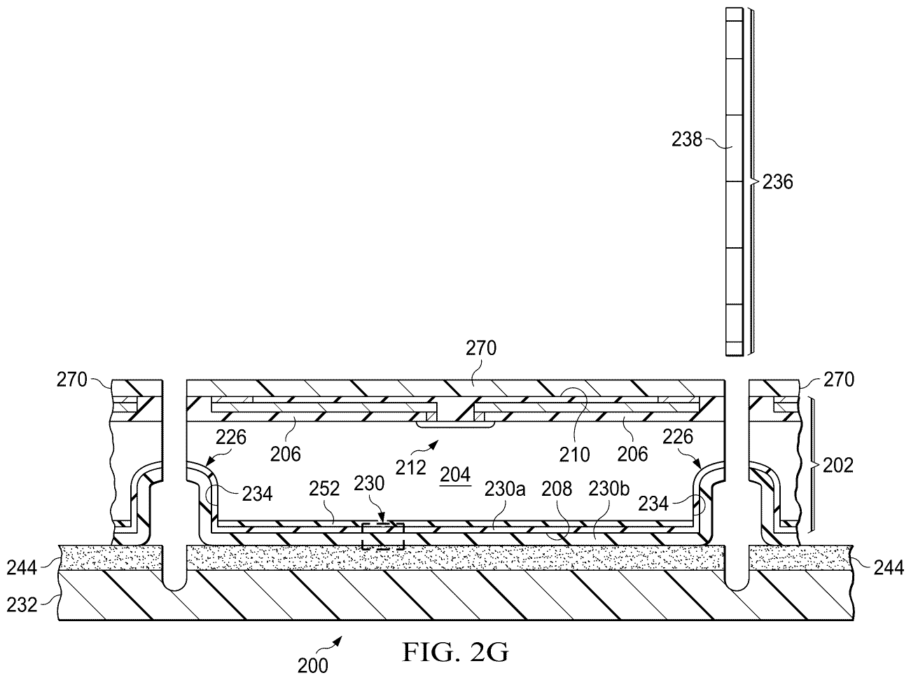

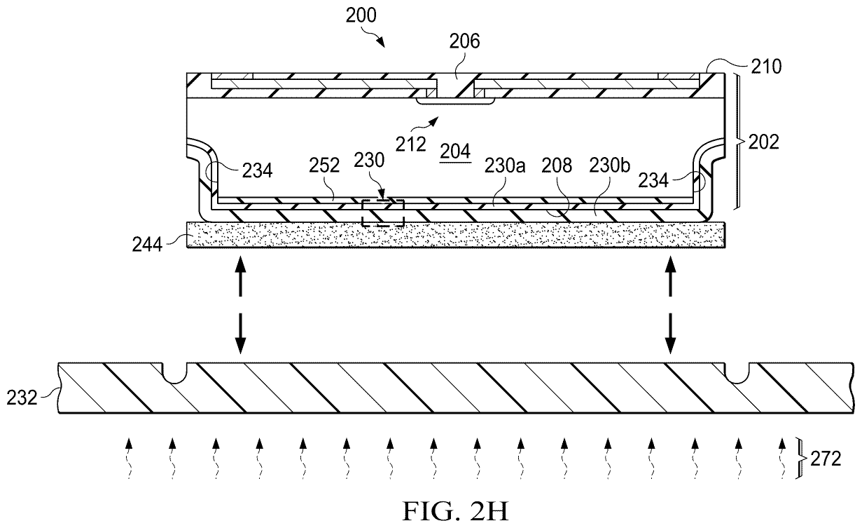

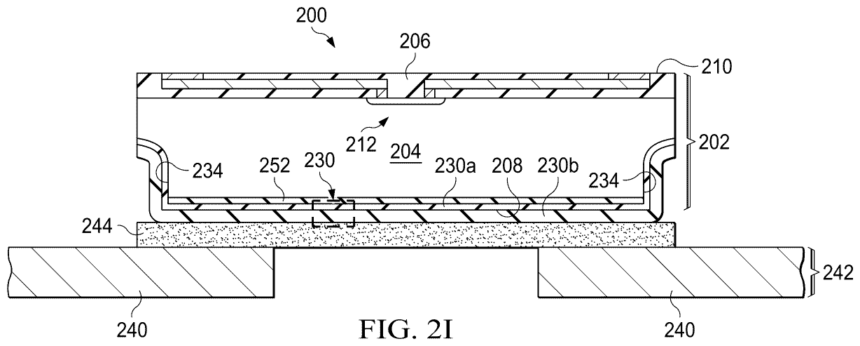

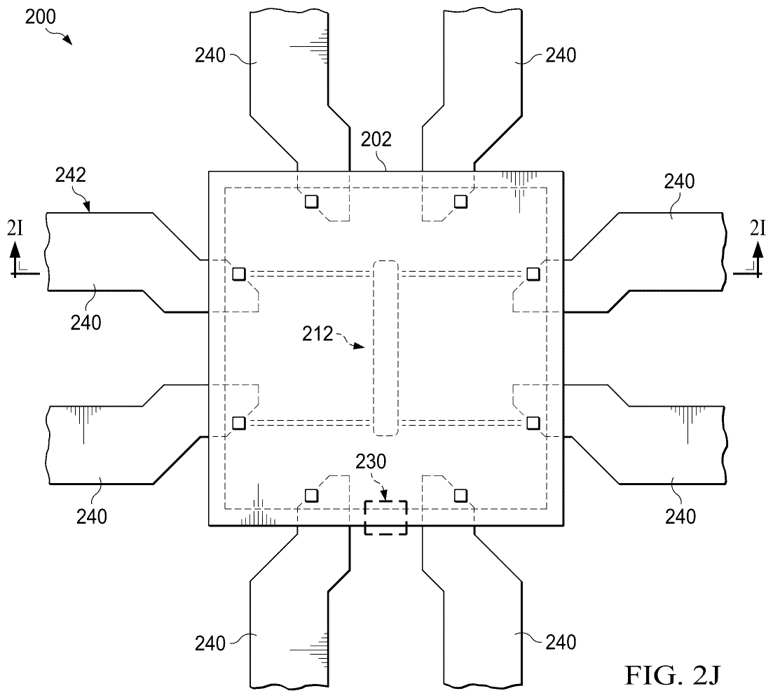

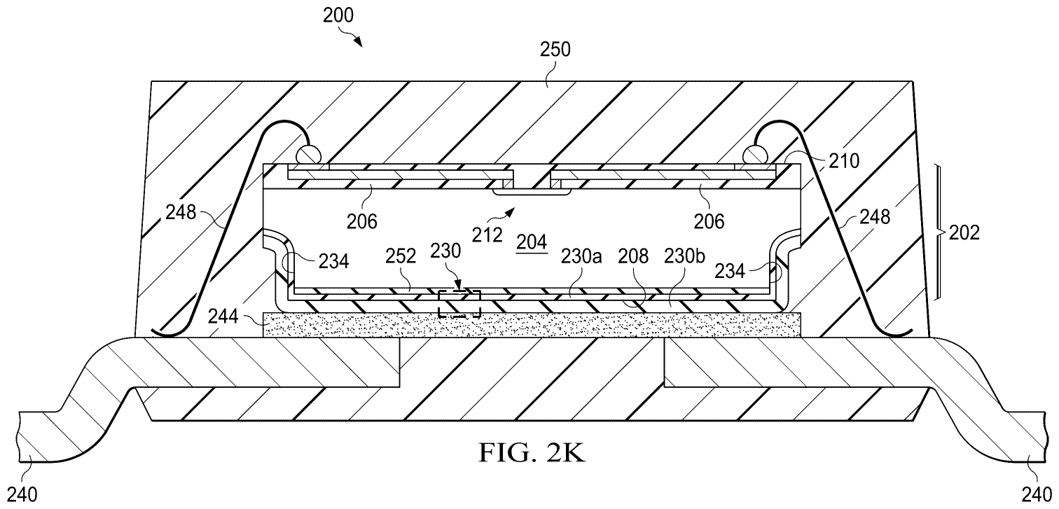

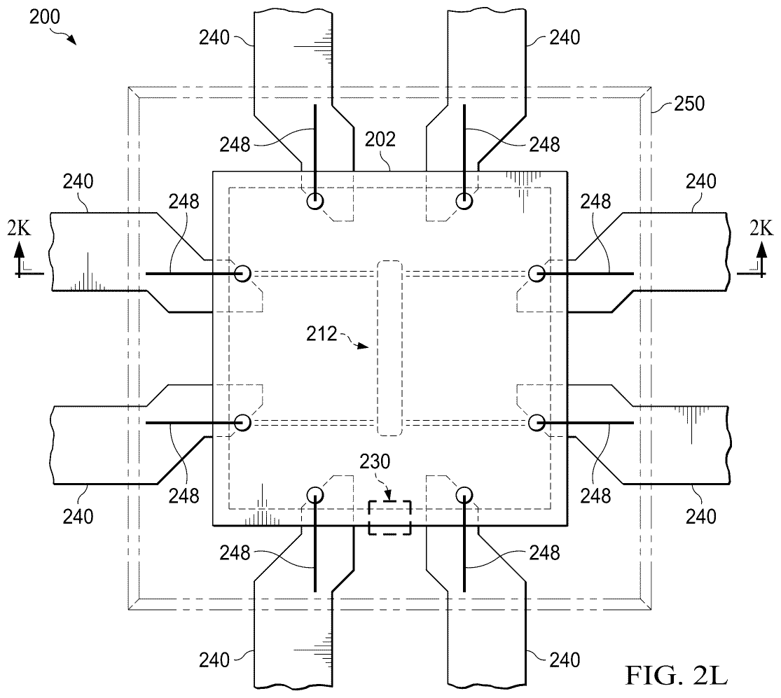

FIG. 2A through FIG. 2L are cross-sections and top views of another example semiconductor package, depicted in stages of another example method of formation. Referring to FIG. 2A, which is a cross section, the semiconductor package 200 includes a microelectronic die 202. The microelectronic die 202 may be manifested as any of the devices disclosed in reference to the microelectronic die 102 of FIG. 1A. The microelectronic die 202 includes a substrate 204 that is electrically conductive, and includes an interconnect region 206 on the substrate 204. The substrate 204 has a back surface 208 located opposite from the interconnect region 206. The substrate 204 may include a dielectric layer 252, such as silicon dioxide or silicon nitride, at the back surface 208, as a result of fabrication steps used to form the microelectronic die 202. The microelectronic die 202 has a connection surface 210 on the interconnect region 206, located opposite from the substrate 204. The microelectronic die 202 includes an electronic component 212 in the substrate 204, adjacent to the interconnect region 206. In this example, the electronic component 212 is depicted as a well resistor 212, which may be part of a sensor, such as a temperature sensor. Other manifestations for the electronic component 212 are within the scope of this example. The connection surface 210 includes bond pads or other input/output structures that are electrically connected to the electronic component 212 through conductive members in the interconnect region 206. The substrate 204, which may be part of a wafer or other semiconductor fabrication workpiece, extends laterally past boundaries of the microelectronic die 202.

The microelectronic die 202 is attached to a processing support structure 222 at the connection surface 210, through a releasable adhesive 254. In this example, the processing support structure 222 may be implemented as a transparent wafer, such as a glass wafer, or a sapphire wafer, may be implemented as a polymer lamina of polycarbonate, polyethersulfone, or polyether imide, or may be implemented as a silicon wafer, by way of example.

In one version of this example, the releasable adhesive 254 may be a single layer of thermoplastic adhesive or thermosetting adhesive. Examples of single layer releasable adhesives include rosin-urethane, acrylic, polyimide, polyetheretherketone (PEEK), polypropylenecarbonate (PPC), polyglycidylmethacrylate (PGMA), and polyisobutene (PIB). In another version in which the processing support structure 222 is implemented as a transparent wafer, the releasable adhesive 254 may include a curable resin layer contacting the connection surface 210 and a light-to-heat conversion layer, sometimes referred to as a photothermal conversion layer, between the processing support structure 222 and the curable resin layer. Examples of curable resin layers include proprietary polymers from 3M Company, Brewer Science, Inc., and Daetec LLC. The light-to-heat conversion layer may include carbon particles in an acrylate binder, or may include a metal film light absorbing layer. In a further version in which the processing support structure 222 is implemented as a silicon wafer, the releasable adhesive 254 may include an inorganic release material that decomposes upon exposure to infrared (IR) laser radiation through the silicon wafer. The inorganic release material is available from the EV Group.

Referring to FIG. 2B, which is a cross section, a protective polymer layer 256 may be formed on the back surface 208, to protect the back surface 208 from debris during a subsequent saw process. Substrate material is removed from the substrate 204 to form isolation kerfs 226 extending from the back surface 208, through the dielectric layer 252, if present, toward the connection surface 210. In this example, the substrate material may be removed by a saw process 258 using a wide saw blade 260. The isolation kerfs 226 may extend approximately halfway through the substrate 204, as depicted in FIG. 2B. Alternatively, the isolation kerfs 226 may extend more than halfway through the substrate 204, or less than halfway through the substrate 204.

After the isolation kerfs 226 are formed, the protective polymer layer 256, if present, may be removed. The protective polymer layer 256 may be removed by a solvent spray or an atmospheric plasma process, for example.

Referring to FIG. 2C, which is a cross section, a first isolation dielectric sublayer 230a of an isolation dielectric layer 230 is formed on the back surface 208 and in the isolation kerfs 226. In this example, the first isolation dielectric sublayer 230a may include primarily inorganic dielectric material, and may be formed by a first plasma enhanced chemical vapor deposition (PECVD) process 262 using tetraethyl orthosilicate (TEOS), formally named tetraethoxysilane, and oxygen, denoted in FIG. 2C as “TEOS” and O₂”, respectively. Other compositions for, and processes for forming, the first isolation dielectric sublayer 230a are within the scope of this invention. The first isolation dielectric sublayer 230a may be a conformal layer, that is, may have a thickness on sidewalls of the isolation kerfs 226 that is less than, or equal to, a thickness of the first isolation dielectric sublayer 230a on the back surface 208, as depicted in FIG. 2C.

Referring to FIG. 2D, which is a cross section, a second isolation dielectric sublayer 230b of the isolation dielectric layer 230 is formed on the first isolation dielectric sublayer 230a, over the back surface 208 and extending into the isolation kerfs 226. In this example, the second isolation dielectric sublayer 230b may also include primarily inorganic dielectric material, and may be formed by a second PECVD process 264 using bis (tertiary-butylamino) silane (BTBAS), and ammonia, denoted in FIG. 2D as “BTBAS” and NH₃”, respectively. Other compositions for, and processes for forming, the second isolation dielectric sublayer 230b are within the scope of this invention. The second isolation dielectric sublayer 230b may be a conformal layer, as depicted in FIG. 2D.

The releasable adhesive 254 may have an operational temperature sufficient to provide support to the microelectronic die 202 during the first PECVD process 262 and the second PECVD process 264. Having the isolation dielectric layer 230 include primarily inorganic material may provide a higher dielectric breakdown strength and longer reliability than organic dielectric material.

Referring to FIG. 2E, which is a cross section, the microelectronic die 202 is inverted and the isolation dielectric layer 230 is attached to a die attach film 244. The die attach film 244 is attached to a dicing tape 232. The dicing tape 232 may be implemented as a thermal release tape or a UV release tape, by way of example.

Subsequently, the releasable adhesive 254 is treated to release the processing support structure 222 from the microelectronic die 202. In the version of this example in which the releasable adhesive 254 includes the light-to-heat conversion layer, the releasable adhesive 254 may be treated using a scanning laser 266 to irradiate the light-to-heat conversion layer with infrared radiation, which converts the infrared radiation to heat, reducing adhesion of the releasable adhesive 254 to the processing support structure 222. The processing support structure 222 is subsequently removed from the releasable adhesive 254 by lifting or sliding, leaving a portion of the releasable adhesive 254 on the connection surface 210. The die attach film 244 and the dicing tape 232 support the microelectronic die 202 while the processing support structure 222 is removed.

Referring to FIG. 2F, which is a cross section, the remaining portion of the releasable adhesive 254 on the connection surface 210 is removed. The remaining portion of the releasable adhesive 254 may be removed by a solvent spray process 268, by way of example. Other methods for removing the remaining portion of the releasable adhesive 254, such as exposure to ozone or oxygen radicals, are within the scope of this example. FIG. 2F depicts removal of the remaining portion of the releasable adhesive 254 partway to completion.

Referring to FIG. 2G, which is a cross section, the microelectronic die 202 and the die attach film 244 are singulated through the isolation kerfs 226, leaving the isolation dielectric layer 230 on perimeter sidewalls 234 of the substrate 204. In this example, the isolation dielectric layer 230 on the perimeter sidewalls 234 extends around all sides of the perimeter sidewalls 234. The microelectronic die 202 and the die attach film 244 may be singulated by a saw process 236 using a diamond saw blade 238, as indicated in FIG. 2G. Other methods of singulating the microelectronic die 202 and the die attach film 244 are within the scope of this example. The connection surface 210 may be coated with a protective film 270, while the microelectronic die 202 is singulated. The protective film 270 is subsequently removed.

Referring to FIG. 2H, which is a cross section, the dicing tape 232 is separated from the die attach film 244. In versions of this example in which the dicing tape 232 is implemented as a UV release tape, the dicing tape 232 may be separated by exposing the dicing tape 232 to UV radiation 272, as depicted schematically in FIG. 2H. In versions of this example in which the dicing tape 232 is implemented as a heat release tape, the dicing tape 232 may be separated by heating the dicing tape 232 in a heating process, such as a hot plate process. In versions of this example in which the dicing tape 232 is implemented as a peel release tape, the dicing tape 232 may be separated by a peeling process. The microelectronic die 202 and the die attach film 244 may be lifted from the dicing tape 232 by pick-and-place equipment, not specifically shown.

Referring to FIG. 2I and FIG. 2J, which are a cross section and a top view, respectively, the isolation dielectric layer 230 is attached to leads 240 of a lead frame 242. The leads 240 are electrically conductive members of the lead frame 242. The isolation dielectric layer 230 is attached to the leads 240 though the die attach film 244, which provides a die attach material 244 in this example. The isolation dielectric layer 230 extends along the perimeter sidewalls 234, so that the substrate 204 is advantageously isolated by the isolation dielectric layer 230 from any electrically conductive debris from the saw process 236 of FIG. 2G which may fall on the leads 240.

Referring to FIG. 2K and FIG. 2L, which are a cross section and a top view, respectively, electrical connections 248 are formed between the microelectronic die 202 at the connection surface 210 and the leads 240. The leads 240 are electrically connected to the electronic component 212 through the electrical connections 248 and interconnect lines and vias in the interconnect region 206, as indicated in FIG. 2K. A packaging material 250 is formed on the microelectronic die 202 and the leads 240. The leads 240 are severed from the lead frame 242 of FIG. 21 and FIG. 2J. The leads 240, which are exposed at an exterior of the semiconductor package 200, are shaped to form gull wing leads, as indicated in FIG. 2K.

The isolation dielectric layer 230 electrically isolates the substrate 204 from the leads 240 which extend under the substrate 204, advantageously enabling the semiconductor package 200 to be reliably operated with different potentials on the leads 240.

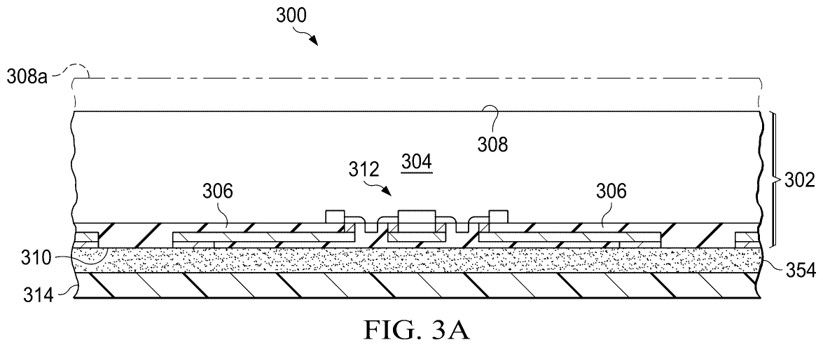

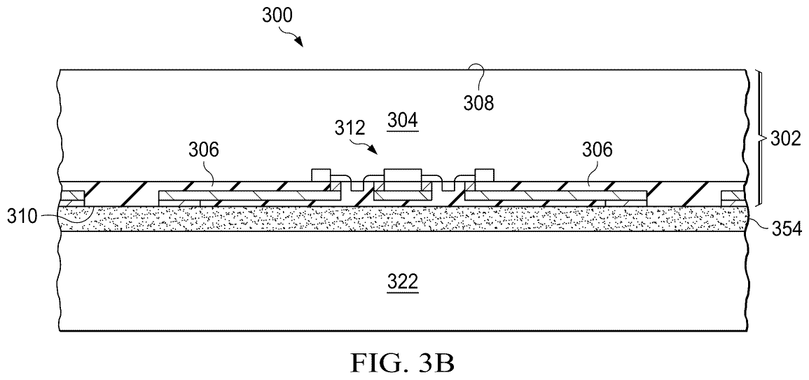

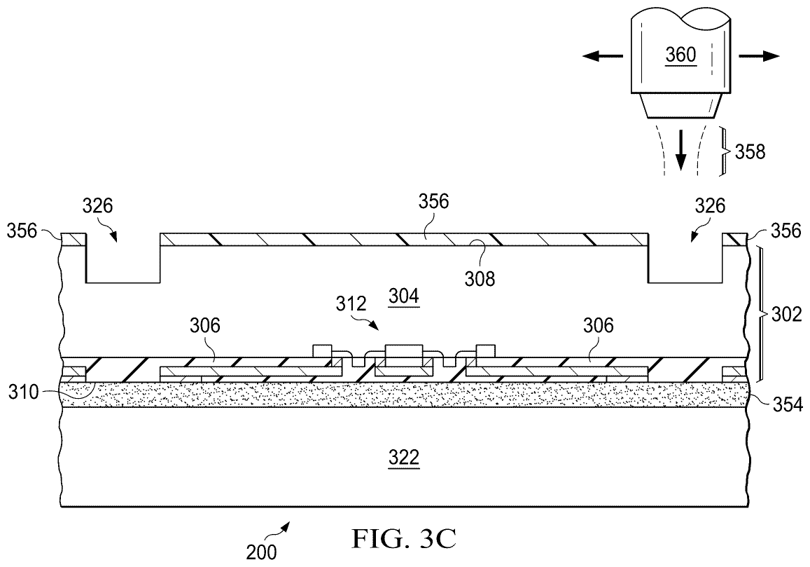

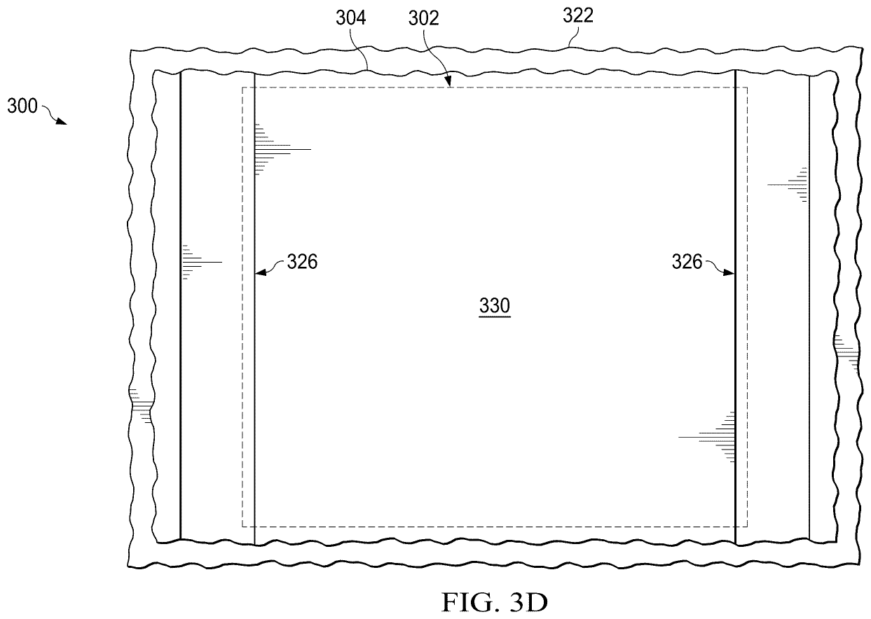

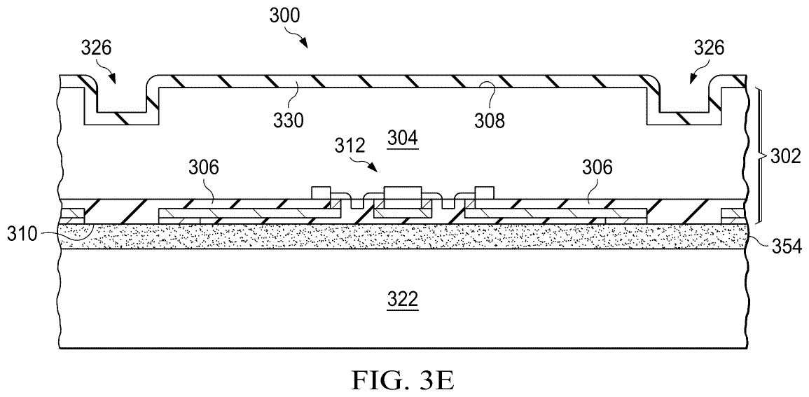

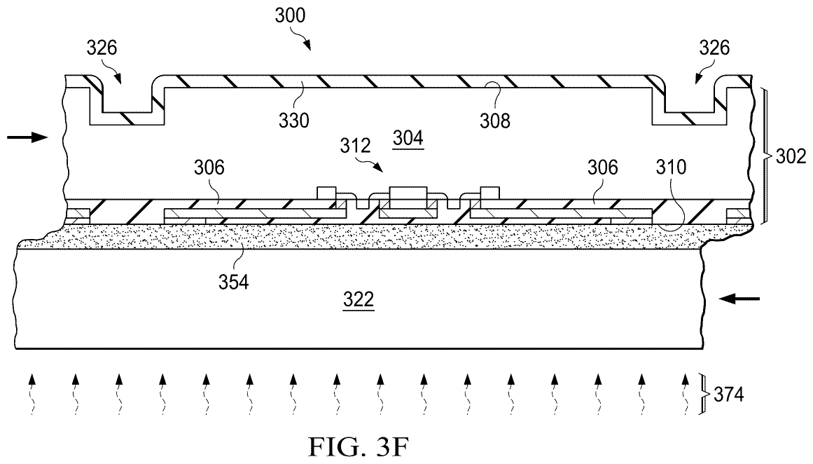

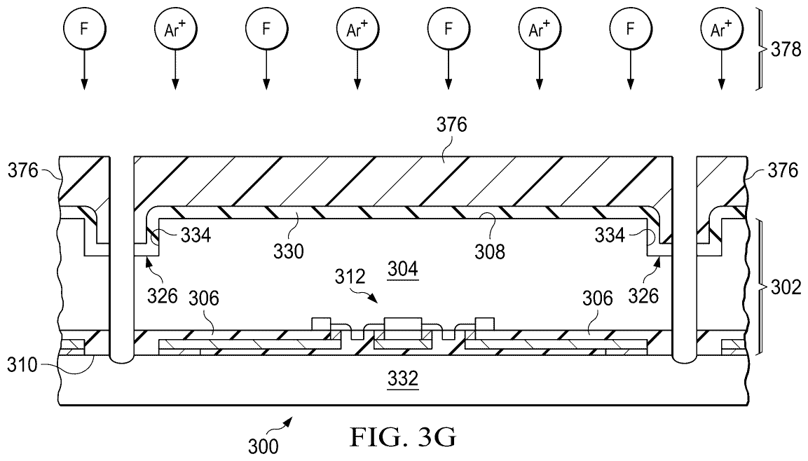

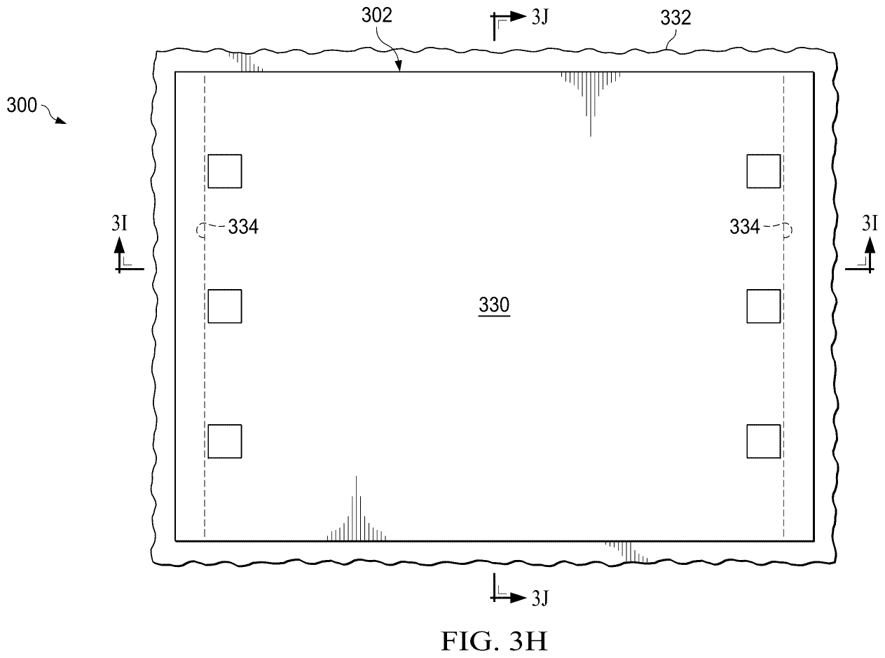

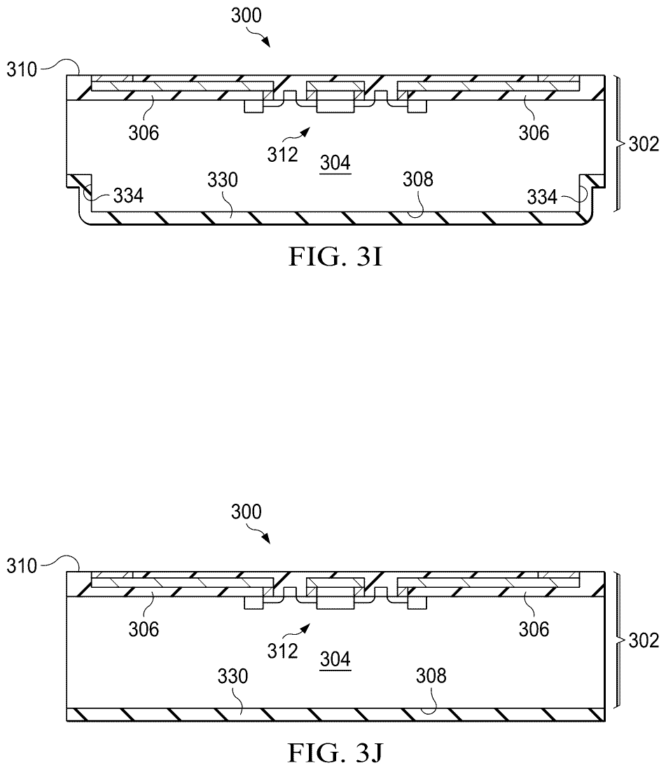

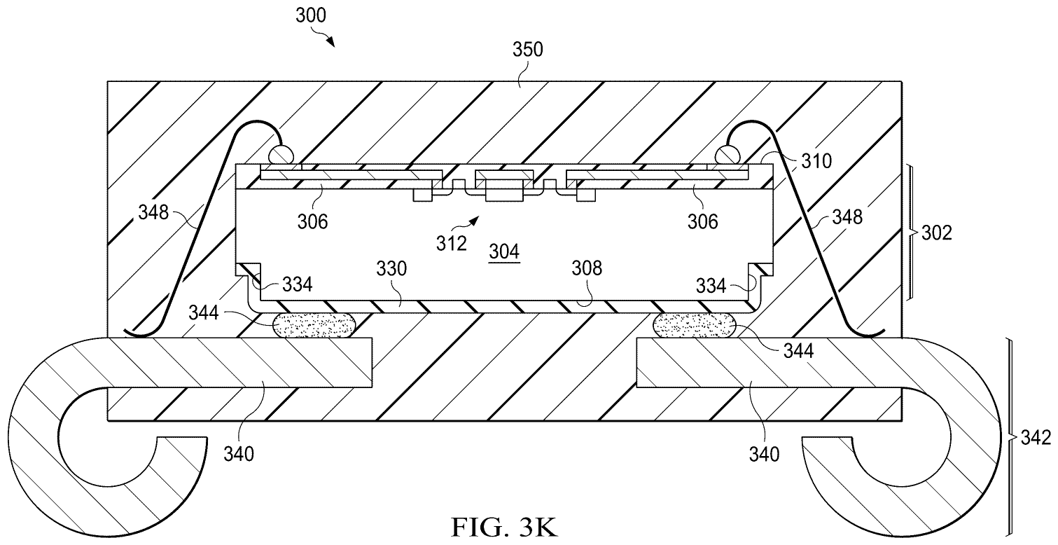

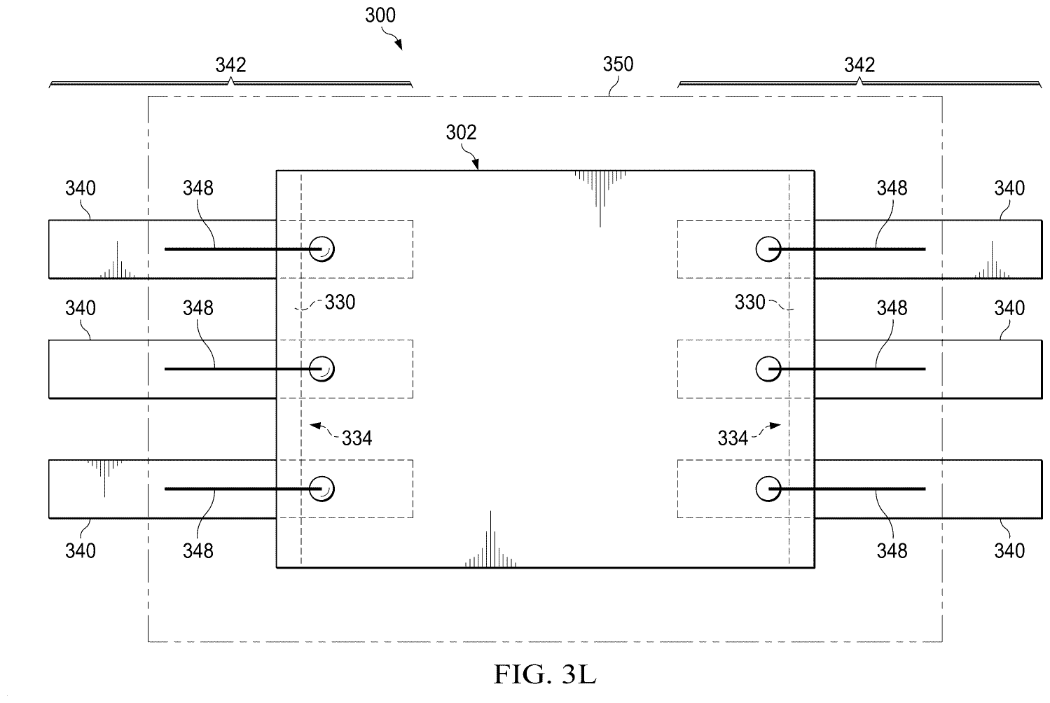

FIG. 3A through FIG. 3L are cross-sections, top views, and a bottom view of a further example semiconductor package, depicted in stages of a further example method of formation. Referring to FIG. 3A, which is a cross section, the semiconductor package 300 includes a microelectronic die 302. The microelectronic die 302 includes a substrate 304 that is electrically conductive. The microelectronic die 302 includes an interconnect region 306 on the substrate 304. The substrate 304 has a back surface 308 located opposite from the interconnect region 306. The microelectronic die 302 has a connection surface 310 on the interconnect region 306, located opposite from the substrate 304. The microelectronic die 302 includes an electronic component 312 in the substrate 304, adjacent to, and possibly extending into, the interconnect region 306. In this example, the electronic component 312 is depicted as a coupled pair of MOS transistors. Other manifestations for the electronic component 312 are within the scope of this example. The connection surface 310 includes bond pads or other input/output structures that are electrically connected to the electronic component 312 through conductive members in the interconnect region 306.

The microelectronic die 302 is attached to a backside process tape 314 at the connection surface 310, thus exposing the back surface 308 of the substrate 304. A portion of the substrate 304 is removed at the back surface 308. FIG. 3A depicts the microelectronic die 302 after the portion of the substrate 304 is removed. The initial back surface 308a is shown in dashed lines. The portion of the substrate 304 may be removed by a back grind process, by a CMP process, by an etch process, or by another method. In this example, less than half of the substrate 304 may be removed. The backside process tape 314 is subsequently removed from the connection surface 310. The backside process tape 314 may be heated, exposed to UV radiation, or be peeled to remove the backside process tape 314 from the connection surface 310. After the backside process tape 314 is removed, any residue, such as remaining adhesive, not specifically shown, on the connection surface 310 may be removed.

Referring to FIG. 3B, which is a cross section, the microelectronic die 302 is attached to a processing support structure 322 at the connection surface 310, through a releasable adhesive 354. In this example, the processing support structure 322 may be implemented as a silicon wafer. The releasable adhesive 354 may be a single layer of thermoplastic adhesive. Other implementations of the processing support structure 322 and the releasable adhesive 354 are within the scope of this example.

Referring to FIG. 3C and FIG. 3D, which are a cross section and a bottom view, respectively, a protective polymer layer 356 may be formed on the back surface 308, to protect the back surface 308 from debris during a subsequent laser ablation process. Substrate material is removed from the substrate 304 to form isolation kerfs 326 extending from the back surface 308 toward the connection surface 310. In this example, the substrate material may be removed by a laser ablation process 358 using a laser 360. The laser 360 may provide UV radiation, visible radiation, or near infrared radiation (for example, having a wavelength of 700 nanometers to 1.1 microns). The laser 360 may operate in a pulsed mode, to reduce heating of the remaining substrate material. The isolation kerfs 326 may extend from 25 percent through the substrate 304 to 75 percent through the substrate 304, by way of example. In this example, the isolation kerfs 326 may be formed along only two opposite sides of the microelectronic die 302, which may advantageously reduce fabrication cost of the semiconductor package 300. After the isolation kerfs 326 are formed, the protective polymer layer 356, if present, may be removed.

Referring to FIG. 3E, which is a cross section, an isolation dielectric layer 330 is formed on the back surface 308 and in the isolation kerfs 326. In this example, the isolation dielectric layer 330 may include primarily organic dielectric material, such as a hydrocarbon polymer or a silicone polymer. The isolation dielectric layer 330 may be formed by a vacuum vapor phase transport process, suitable for parylene, for example. The isolation dielectric layer 330 may be formed by an initiated chemical vapor deposition (iCVD) process, in which reactant organic monomers are transported to the microelectronic die 302 and react on the back surface 308 and in the isolation kerfs 326 to form the isolation dielectric layer 330. Other compositions for, and processes for forming, the isolation dielectric layer 330 are within the scope of this invention. The isolation dielectric layer 330 may be a conformal layer, as depicted in FIG. 3E.

Referring to FIG. 3F, which is a cross section, the processing support structure 322 is separated from the microelectronic die 302. The processing support structure 322 may be separated from the microelectronic die 302 by heating the releasable adhesive 354 using a heating process 374, such as a hot plate process, to soften the releasable adhesive 354, followed by sliding the processing support structure 322 and the microelectronic die 302 laterally with respect to each other until the processing support structure 322 is separated from the microelectronic die 302. Other methods for separating the processing support structure 322 from the microelectronic die 302 are within the scope of this example.

Referring to FIG. 3G and FIG. 3H, which are a cross section and a top view, respectively, a singulation etch mask 376 is formed on the isolation dielectric layer 330, exposing the isolation dielectric layer 330 in singulation lanes around a perimeter of the microelectronic die 302. The singulation etch mask 376 may have a composition similar to the kerf etch mask 124 of FIG. 1F, and may be formed by a similar process. A singulation substrate 332, which may be implemented as a dicing tape 332 or a more rigid substrate is attached to the connection surface 310.

The microelectronic die 302 is singulated around the perimeter of the microelectronic die 302, through the isolation kerfs 326 along the two opposite sides of the microelectronic die 302, leaving the isolation dielectric layer 330 on perimeter sidewalls 334 of the substrate 304 along the isolation kerfs 326. In this example, the isolation dielectric layer 330 on the perimeter sidewalls 334 along the two opposite sides of the microelectronic die 302. The microelectronic die 302 may be singulated by a deep RIE process 378, by way of example.

The microelectronic die 302 is subsequently separated from the singulation substrate 332. The singulation substrate 332 may be expanded to facilitate separation from the microelectronic die 302. The microelectronic die 302 may be separated from the singulation substrate 332 by applying heat or UV radiation to the singulation substrate 332 to reduce adhesion to the connection surface 310, followed by lifting the microelectronic die 302 from the singulation substrate 332.

FIG. 3I and FIG. 3J are cross sections of the microelectronic die 302 after separation from the singulation substrate 332 of FIG. 3G and FIG. 3H. The isolation dielectric layer 330 is continuous along the back surface 308. The isolation dielectric layer 330 extends from the back surface 308 toward the connection surface 310 along the perimeter sidewalls 334 along the two opposite sides of the microelectronic die 302, as depicted in FIG. 3I. In this example, the isolation dielectric layer 330 does not extend toward the connection surface 310 along sides of the substrate 304 on the remaining two sides of the microelectronic die 302, as depicted in FIG. 3J.

Referring to FIG. 3K and FIG. 3L, which are a cross section and a top view, respectively, the isolation dielectric layer 330 is attached to leads 340, which are electrically conductive members of a lead frame 342. In this example, the leads 340 extend under the microelectronic die 302 only on the two sides of the microelectronic die 302 having the isolation dielectric layer 330 along the perimeter sidewalls 334, as depicted in FIG. 3L. The isolation dielectric layer 330 is attached to the leads 340 though a die attach material 344. Such as a die attach paste 344, as depicted in FIG. 3K. On the two sides of the microelectronic die 302 having the isolation dielectric layer 330 along the perimeter sidewalls 334, the isolation dielectric layer 330 extends vertically past the die attach material 344 along the perimeter sidewalls 334, so that the substrate 304 is isolated from the die attach material 344 by the isolation dielectric layer 330. The die attach material 344 does not directly contact the substrate 304.

Electrical connections 348 are formed between the microelectronic die 302 at the connection surface 310 and the leads 340. The leads 340 are electrically connected to the electronic component 312 through the electrical connections 348 and interconnect lines and vias in the interconnect region 306, as indicated in FIG. 3K.

A packaging material 350 is formed on the microelectronic die 302 and the leads 340. The leads 340 are severed from the lead frame 342. The leads 340, which are exposed at an exterior of the semiconductor package 300, are shaped to form J-leads, as indicated in FIG. 3K.

The isolation dielectric layer 330 electrically isolates the substrate 304 from the leads 340 which extend under the substrate 304, advantageously enabling the semiconductor package 300 to be reliably operated with different potentials on the leads 340.

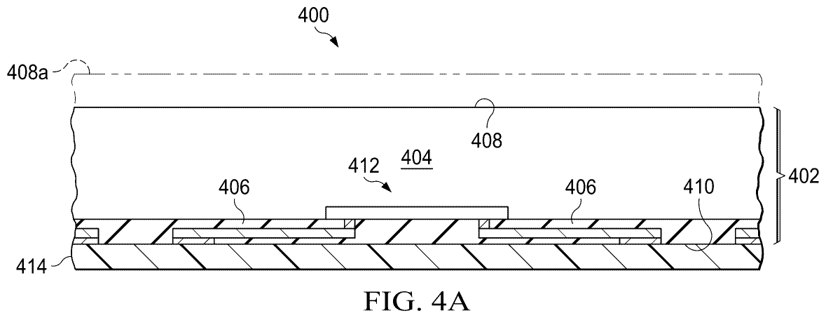

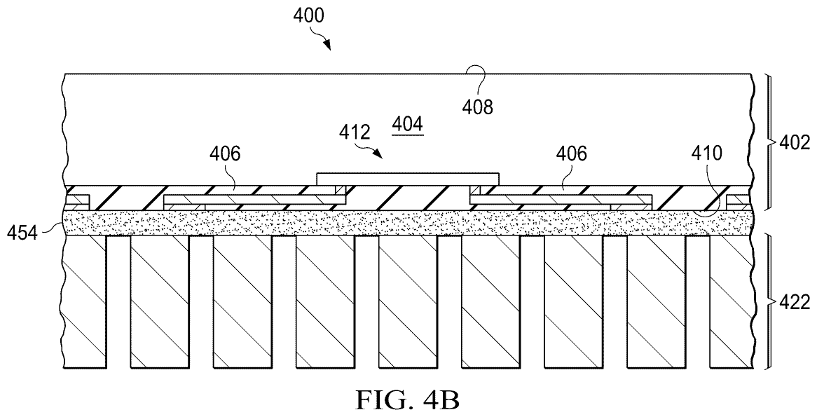

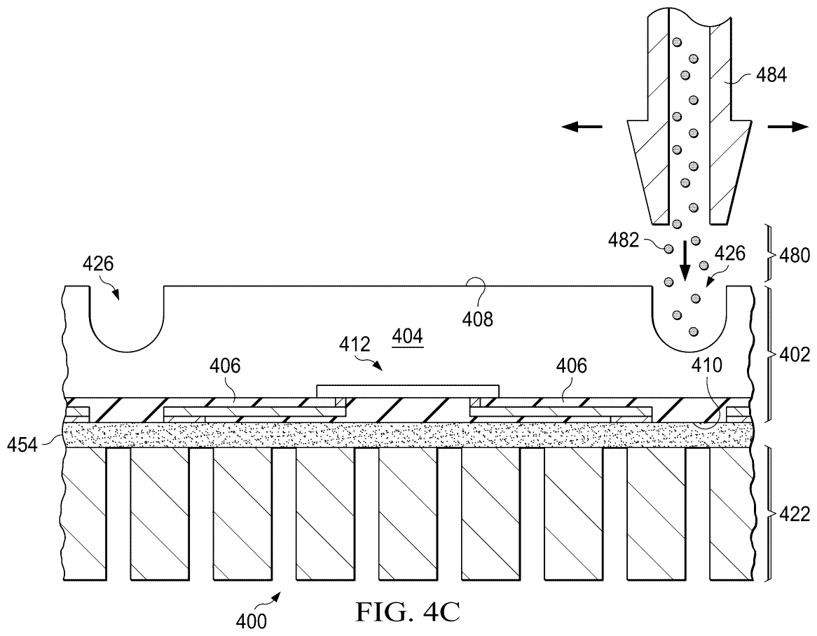

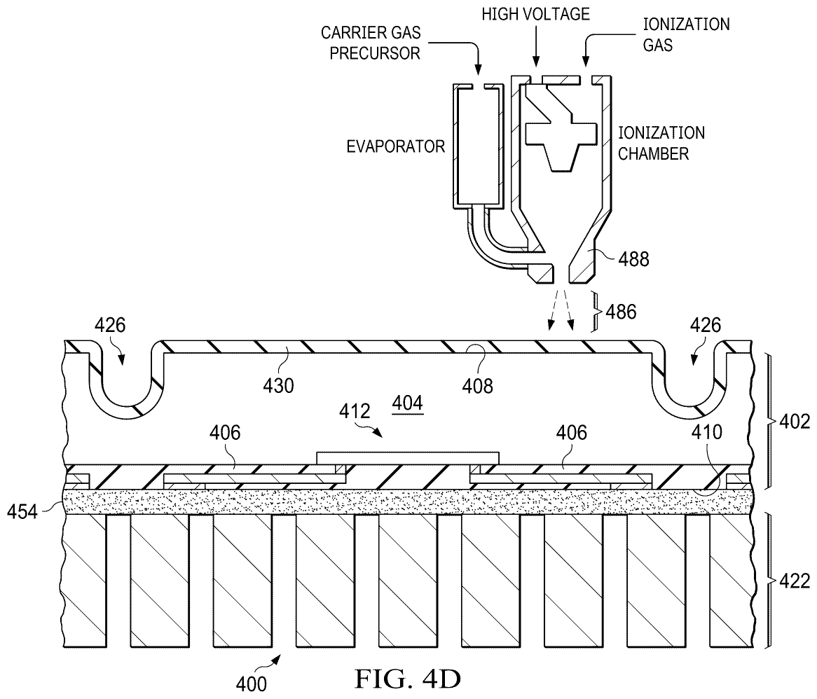

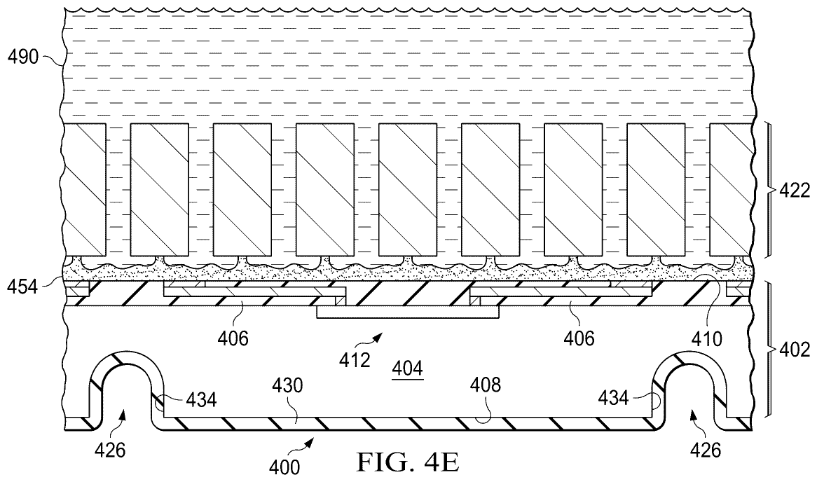

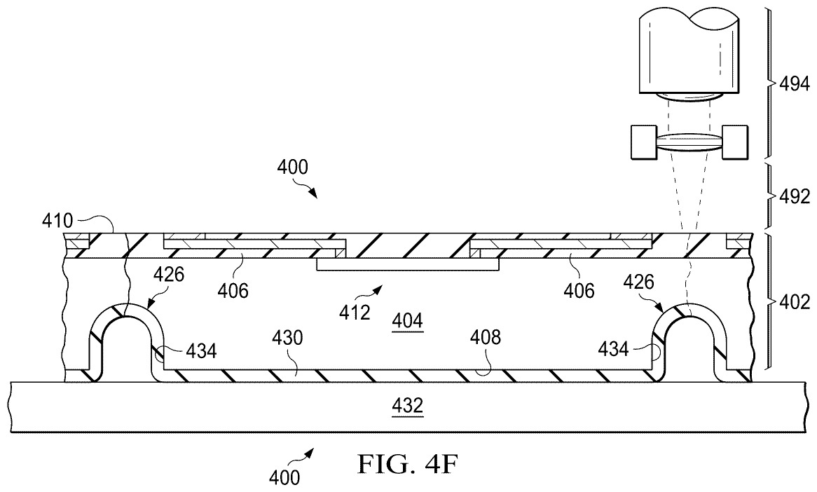

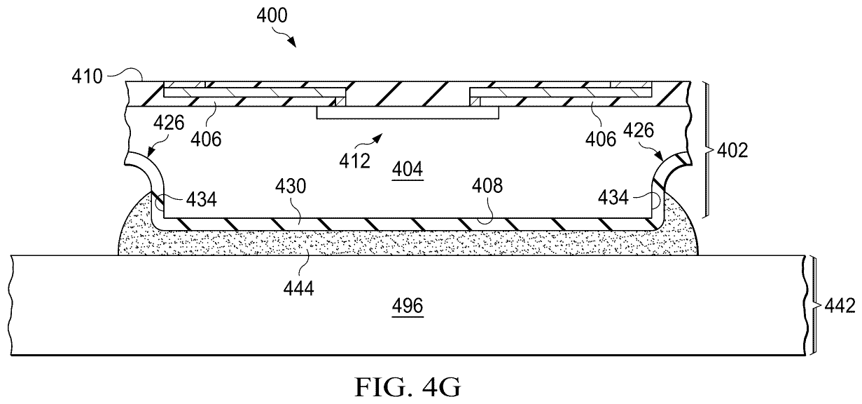

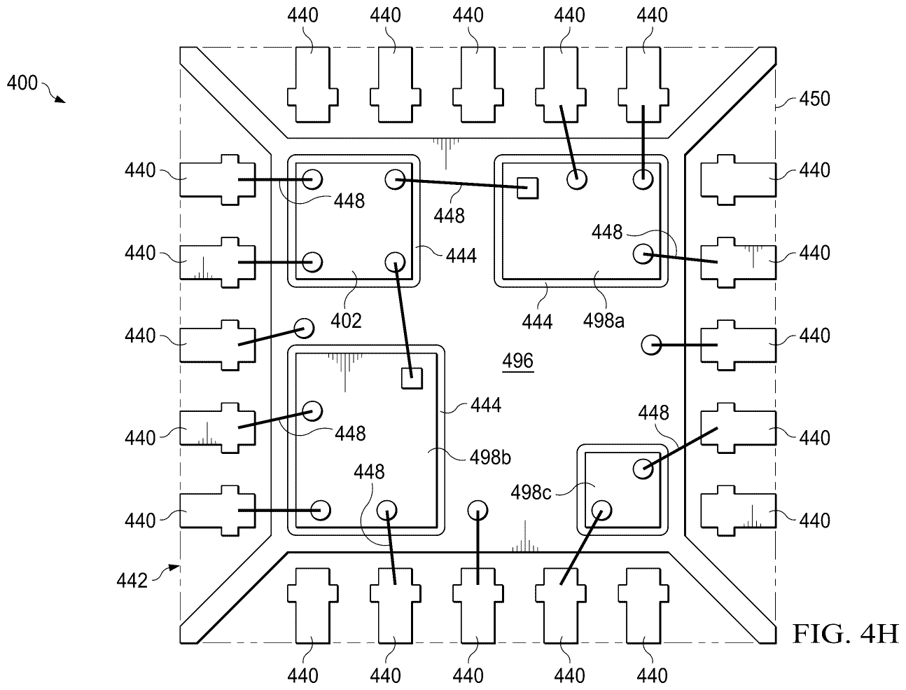

FIG. 4A through FIG. 4H are cross-sections and top views of a further example semiconductor package, depicted in stages of a further example method of formation. Referring to FIG. 4A, which is a cross section, the semiconductor package 400 includes a microelectronic die 402. The microelectronic die 402 includes a substrate 404 that is electrically conductive. The microelectronic die 402 includes an interconnect region 406 on the substrate 404. The substrate 404 has a back surface 408 located opposite from the interconnect region 406, and a connection surface 410 on the interconnect region 406, located opposite from the substrate 404. The microelectronic die 402 includes an electronic component 412 in the substrate 404, adjacent to, and possibly extending into, the interconnect region 406. The connection surface 410 includes bond pads or other input/output structures that are electrically connected to the electronic component 412 through conductive members in the interconnect region 406.

The microelectronic die 402 is attached to a backside process tape 414 at the connection surface 410, thus exposing the back surface 408 of the substrate 404. A portion of the substrate 404 is removed at the back surface 408. The initial back surface 408a is shown in dashed lines. The backside process tape 414 supports the microelectronic die 402 while the portion of the substrate 404 is removed. Subsequently, the backside process tape 414 is removed.

Referring to FIG. 4B, the microelectronic die 402 is attached to a processing support structure 422 at the connection surface 410, through a releasable adhesive 454. In this example, the processing support structure 422 has openings to allow access to the releasable adhesive 454. The openings in the processing support structure 422 may have lateral dimensions on the order of a thickness of the substrate 404, as depicted in FIG. 4B. Alternatively, The openings may have lateral dimensions that are much less than thickness of the substrate 404, for example, less than 10 percent of the thickness of the substrate 404. The releasable adhesive 454 of this example may be a thermoplastic that is soluble in a solvent. The releasable adhesive 454 may be adhered to the microelectronic die 402 and the processing support structure 422 by a thermocompression bonding process, in which the releasable adhesive 454 is heated to a softened state while the microelectronic die 402 and the releasable adhesive 454 are pressed onto opposite faces of the releasable adhesive 454.

Referring to FIG. 4C, substrate material is removed from the substrate 404 to form isolation kerfs 426 extending from the back surface 408 toward the connection surface 410. In this example, the substrate material may be removed by a micro abrasive jet process 480 using sub-micron abrasive particles 482 delivered at high speed by a scanning gas jet nozzle 484. The micro abrasive jet process 480 may be performed in ambient, which may advantageously provide reduced cost compared to a vacuum process, such as an RIE process. The micro abrasive jet process 480 may advantageously produce less stress in the substrate 404 compared to a saw process. Gas from the scanning gas jet nozzle 484 may remove the sub-micron abrasive particles 482 from the back surface 408, eliminating need for a protective layer on the back surface 408, advantageously reducing fabrication costs compared to a laser ablation process.

Referring to FIG. 4D, which is a cross section, an isolation dielectric layer 430 is formed on the back surface 408 and in the isolation kerfs 426. The isolation dielectric layer 430 may include primarily organic dielectric material, such as a hydrocarbon polymer or a silicone polymer. The isolation dielectric layer 430 may be formed by an atmospheric plasma process 486 using an atmospheric plasma generator 488. The atmospheric plasma generator 488 may include an evaporator, labeled “EVAPORATOR” in FIG. 4D, which receives a carrier gas, labeled “CARRIER GAS” in FIG. 4D, such as nitrogen, and a dielectric precursor liquid, labeled “PRECURSOR” in FIG. 4D, such as an amine, a methylated monomer, or an acrylic monomer. The evaporator converts the dielectric precursor liquid to a vapor and mixes the vapor with the carrier gas, and delivers the vapor and carrier gas to an ionization chamber, labeled “IONIZATION CHAMBER” in FIG. 4D, connected to the evaporator. The ionization chamber receives an ionization gas, labeled “IONIZATION GAS” in FIG. 4D, such as air or nitrogen, and receives high voltage, labeled “HIGH VOLTAGE” in FIG. 4D, and ionizes the ionization gas, and mixes the ionized gas with the vapor from the evaporator. The ionization chamber delivers the ionized gas with the vapor in a vapor jet to the back surface 408 and the isolation kerfs 426. The isolation dielectric layer 430 may be a conformal layer, as depicted in FIG. 4D. Alternatively, the atmospheric plasma process 486 may form the isolation dielectric layer 430 with primarily inorganic material by an appropriate change in the dielectric precursor liquid. Using the atmospheric plasma generator 488 to form the isolation dielectric layer 430 may advantageously provide reduced fabrication cost and lower process temperature compared to using vacuum equipment.

Referring to FIG. 4E, which is a cross section, the processing support structure 422 is separated from the microelectronic die 402 by dissolving the releasable adhesive 454 in a solvent 490. The openings in the processing support structure 422 allow access by the solvent 490 to the releasable adhesive 454, facilitating dissolution of the releasable adhesive 454. The processing support structure 422 may be lifted from the microelectronic die 402 when the releasable adhesive 454 is sufficiently dissolved, which may advantageously provide lower stress on the substrate 404 than other methods of separating the processing support structure 422 from the microelectronic die 402.

Referring to FIG. 4F, which is a cross section, the microelectronic die 402 is attached to a singulation substrate 432 at the connection surface 410. The singulation substrate 432 may be implemented as a dicing tape 432 or a more rigid substrate.

The microelectronic die 402 is singulated through the isolation kerfs 426, leaving the isolation dielectric layer 430 on perimeter sidewalls 434 of the substrate 404. The microelectronic die 402 may be singulated by a laser dicing process 492 using a dicing laser 494 which generates fracture lines in the substrate 404 over the isolation kerfs 426. The substrate 404 is subsequently cleaved along the fracture lines, singulating the microelectronic die 402. The laser dicing process 492 may advantageously generate less stress in the substrate 404 compared to other dicing processes. The microelectronic die 402 is subsequently separated from the singulation substrate 432.

Referring to FIG. 4G, which is a cross section, the microelectronic die 402 is attached to a die pad 496 of a lead frame 442. The die pad 496 is an electrically conductive member of the lead frame 442. The die pad 496 may extend laterally past the microelectronic die 402 on all sides. The microelectronic die 402 is attached to the die pad 496 at the isolation dielectric layer 430 by a die attach material 444, such as a die attach paste 444, as depicted in FIG. 4G. The isolation dielectric layer 430 extends vertically past the die attach material 444 along the perimeter sidewalls 434. The die attach material 444 does not directly contact the substrate 404. The substrate 404 is isolated from the die pad 496 by the isolation dielectric layer 430.

Referring to FIG. 4H, which is a top view, additional microelectronic die 498a, 498b, and 498c are attached to the die pad 496. The additional microelectronic die 498a, 498b, and 498c may be attached to the die pad 496 through the die attach material 444, or by other materials.

Electrical connections 448 are formed between the microelectronic die 402 and leads 440 of the lead frame 442, and between the microelectronic die 402 and one or more of the additional microelectronic die 498a, 498b, and 498c, as indicated in FIG. 4H. The electrical connections 448 are electrically connected to the bond pads at the connection surface 410, which are electrically connected to the electronic component 412 through the interconnect region 406, as indicated in FIG. 4G. Additional instances of the electrical connections 448 are formed between the additional microelectronic die 498a, 498b, and 498c and the leads 440.

A packaging material 450 is formed on the microelectronic die 402, the additional microelectronic die 498a, 498b, and 498c, the electrical connections 448, the die pad 496, and the leads 440. In this example, the leads 440 are severed from the lead frame 442 after the packaging material 450 is formed. The semiconductor package 400 of this example may be a quad flat no-lead (QFN) package, as depicted in FIG. 4H. The die pad 496 may be exposed at a bottom surface of the semiconductor package 400.

The isolation dielectric layer 430 electrically isolates the substrate 404 from the die pad 496, advantageously enabling the semiconductor package 400 to be reliably operated with a different potential on the substrate 404 than on the die pad 496. The semiconductor package 400 may be reliably operated with a different potential on the substrate 404 than on substrates of the additional microelectronic die 498a, 498b, and 498c.

Various features of the semiconductor packages, and various steps in the methods of formation, disclosed herein may be combined in other manifestations of semiconductor packages and methods of formation. Any of the substrates 104, 204, 304, and 404 may have more substrate material removed at the back surface 108, 208, 308, and 408, respectively, than disclosed in the corresponding examples. Any of the substrates 104, 204, 304, and 404 may have less substrate material removed at the back surface 108, 208, 308, and 408, respectively, than disclosed in the corresponding examples. Any of the substrates 104, 204, 304, and 404 may have no substrate material removed at the back surface 108, 208, 308, and 408, respectively.

Any of the microelectronic die 102, 202, 302, and 402 may use a rigid substrate, as disclosed in reference to FIG. 1D through FIG. 1H, a transparent wafer with a releasable adhesive or a polymer lamina with a releasable adhesive, as disclosed in reference to FIG. 2A through FIG. 2D, a silicon wafer, as disclosed in reference to FIG. 3B through FIG. 3F, or a processing support structure having openings with a thermoplastic that is soluble in a solvent, as disclosed in reference to FIG. 4B through FIG. 4E, for supporting the corresponding substrate 104, 204, 304, and 404 during formation of the isolation kerfs 126, 226, 326, and 426, respectively. Any of the isolation kerfs 126, 226, 326, and 426 may be formed by a deep RIE process, as disclosed in reference to FIG. 1F, a saw process, as disclosed in reference to FIG. 2B, a laser ablation process, as disclosed in reference to FIG. 3C, or a micro abrasive jet process, as disclosed in reference to FIG. 4C

Any of the isolation dielectric layers 130, 230, 330, and 430 may include inorganic dielectric material, as disclosed in reference to FIG. 2C, FIG. 2D, or FIG. 4D. Any of the isolation dielectric layers 130, 230, 330, and 430 may include organic dielectric material, as disclosed in reference to FIG. 1G, FIG. 2C, FIG. 2D, FIG. 3E, or FIG. 4D. Any of the isolation dielectric layers 130, 230, 330, and 430 may include filler particles, as disclosed in reference to FIG. 1G. Any of the isolation dielectric layers 130, 230, 330, and 430 may include more than one sublayer, as disclosed in reference to FIG. 2C and FIG. 2D.

Any of the microelectronic die 102, 202, 302, and 402 may be singulated by a saw process, as disclosed in reference to FIG. 1L or FIG. 2G. Any of the microelectronic die 102, 202, 302, and 402 may be singulated by a deep RIE process, as disclosed in reference to FIG. 3G. Any of the microelectronic die 102, 202, 302, and 402 may be singulated by a laser dicing process, as disclosed in reference to FIG. 4F.

Any of the microelectronic die 102, 202, 302, and 402 may be attached to leads, as disclosed in reference to FIG. 1K and FIG. 1L, FIG. 21 and FIG. 2J, or FIG. 3K and FIG. 3L. Any of the microelectronic die 102, 202, 302, and 402 may be attached to a die pad, as disclosed in reference to FIG. 4G.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and equivalents.

What is claimed is:

1. A semiconductor package, comprising:
a microelectronic die having a substrate, the substrate being electrically conductive, the substrate having a back surface and perimeter sidewalls contiguous with the back surface;
an isolation dielectric layer on the back surface, the isolation dielectric layer extending from the back surface onto the perimeter sidewalls; and
a lead frame, the isolation dielectric layer on the back surface being attached to an electrically conductive member of the lead frame.

2. The semiconductor package of claim 1, wherein the electrically conductive member of the lead frame is a lead of the lead frame.

3. The semiconductor package of claim 2, wherein the electrically conductive member of the lead frame is a die pad of the lead frame.

4. The semiconductor package of claim 1, the lead frame including leads, wherein:
at least two of the leads provide a Hall current path under the microelectronic die;
the isolation dielectric layer on the back surface is attached to the leads that provide the Hall current path; and
the isolation dielectric layer on the back surface is attached to additional leads of the lead frame.

5. The semiconductor package of claim 1, wherein the isolation dielectric layer includes a plurality of sublayers.

6. The semiconductor package of claim 1, wherein the isolation dielectric layer includes an inorganic dielectric material.

7. The semiconductor package of claim 1, wherein the isolation dielectric layer includes an organic dielectric material.

8. The semiconductor package of claim 1, wherein the isolation dielectric layer on the perimeter sidewalls extends around all sides of the microelectronic die.

9. A method of forming a semiconductor package, comprising:
forming isolation kerfs in a substrate of a microelectronic die, the isolation kerfs extending partway into the substrate from a back surface of the substrate;
forming an isolation dielectric layer on the back surface and in the isolation kerfs;
singulating the microelectronic die in the isolation kerfs; and
attaching the isolation dielectric layer on the back surface to an electrically conductive member of a lead frame.

10. The method of claim 9, further comprising removing a portion of the substrate at the back surface, prior to forming the isolation kerfs.

11. The method of claim 9, wherein the electrically conductive member of the lead frame is a lead of the lead frame.

12. The method of claim 9, wherein the electrically conductive member of the lead frame is a die pad of the lead frame.

13. The method of claim 9, wherein forming the isolation kerfs includes sawing into the substrate.

14. The method of claim 9, wherein forming the isolation kerfs includes etching into the substrate.

15. The method of claim 9, wherein forming the isolation dielectric layer includes forming an inorganic dielectric material over the back surface and in the isolation kerfs.

16. The method of claim 9, wherein forming the isolation dielectric layer includes forming an organic dielectric material over the back surface and in the isolation kerfs.

17. The method of claim 9, wherein forming the isolation dielectric layer includes spin coating a dielectric precursor over the back surface and in the isolation kerfs.

18. The method of claim 9, wherein the isolation dielectric layer fills the isolation kerfs.

19. The method of claim 9, wherein forming the isolation dielectric layer includes a plasma enhanced chemical vapor deposition process.

20. The method of claim 9, wherein forming the isolation dielectric layer includes forming a dielectric material by a vapor transport process.
